(19) United States
(12) Patent Application Publication
(10) Pub. No.: US 2025/0056706 A1
(43) Pub. Date: Feb. 13, 2025

(54) APPARATUS AND METHODS FOR GENERATING CONDENSED PLASMOIDS

(71) Applicant: Gaia Securities Limited, Nelson (NZ)

(72) Inventor: Gyorgy Egely, Budakeszi (HU)

(21) Appl. No.: 18/712,216

(22) PCT Filed: Nov. 22, 2022
(86) PCT No.: PCT/NZ2022/050148

§ 371 Date: May 21, 2024

(30) Foreign Application Priority Data
Nov. 22, 2021 (AU) 2021903765
Jul. 22, 2022 (NZ) 790599

(51) Int. Cl. H05H 1/50; G21B 3/00; H05H 1/10

(52) U.S. Cl. CPC H05H 1/50; G21B 3/006; H05H 1/10

(57) ABSTRACT

Apparatus (1) for generating condensed plasmoids. The apparatus (1) includes a reactor (4) with a chamber (15) for containing a reactant gas. A cathode (17) and an anode (18) extend into the chamber (15) with an interelectrode gap formed between the electrodes (17,18). The electrodes (17, 18) are connectable to an electrical circuit (13) having a power supply (12) for applying an electric potential difference between the electrodes (17, 18) to form a plasma of the reactant gas in the interelectrode gap (19). An interelectrode discharge (21) traverses the interelectrode gap (19). The cathode (17) has an electron discharge material (22) from which clusters (63) of electrons emit, thereby generating condensed plasmoids (62) in the interelectrode discharge (21). The electron discharge material (22) includes a semiconductor material.

### TECHNICAL FIELD

The invention relates to apparatus and methods for generating interelectrode discharges via a plasma. In particular, the present invention relates to apparatus and methods for generating condensed plasmoids in a plasma located in an interelectrode gap.

### BACKGROUND ART

In classical physics self-organised aggregates of matter may behave as “pseudo particles” with similar properties to ‘real’ particles. Examples including smoke rings, vortex rings and turbulent vortexes. Such pseudo particles have energy, momentum, and “pseudo mass”. Such pseudo particles collide, exchange energy, momentum and angular momentum, much like ‘real’ particles.

A plasmoid is a form of pseudo particle and is defined as a coherent structure of plasma and magnetic fields. Plasmoids have been proposed to explain natural phenomena such as ball lightning, magnetic bubbles in the magnetosphere, and objects in comet-tails, in the solar wind, in the solar atmosphere and in the heliospheric current sheet. Plasmoids produced in the laboratory include field-reversed configurations, spheromaks, and in dense plasma focuses.

Soliton waves are a known form of pseudo-particle and can form in non-linear mediums. Soliton waves are found as surface waves characterized by low dissipation with a consequently relatively long spatial and temporal life span. These same soliton wave features characterize surface charge waves on non-linear metals. Soliton charge waves on metals can be formed by applying a sudden high level of electric potential across the metal.

When there is a plasma located near the surface of a metal, the soliton surface charge waves are termed “surface plasmons”, or “surface plasmon polaritons”. These plasmoid phenomena have become subjects of increasing experimental investigation in the last few decades.

Surface plasmons are a form of plasmoid that are formed above the surface of a metal. Relevant papers on surface plasmons include:
(B. M. Schasfoort and A. J. Tudas, 2008) The Handbook of Surface Plasmon Resonance.
(Raether, 1988) Surface Plasmons on Smooth and Rough Surface and on Gratings.
(Maier, 2007) Plasmonics: Fundamentals and applications.

Another known pseudo particle, herein referred to as a ‘condensed plasmoid’, is a type of plasmoid characterised by a particularly dense formation of charge in the plasma.

Researchers in the area have attempted various apparatus and methods for generating condensed plasmoids.
(U.S. Pat. No. 5,148,461, 1992) by Shoulders describes condensed plasmoids and an apparatus for generating them. Shoulders defined condensed plasmoids in the following way:
“ . . . a high charge density entity being a relatively discrete, self-contained, negatively charged, high density state of matter that may be produced by the application of a high electrical field between a cathode and an anode. I have named this entity ELECTRUM VALIDUM, abbreviated “EV”, from the Greek “elektron” for electronic charge, and from the Latin “valere” meaning to have power, to be strong, and having the ability to unite.”
(Jaitner, 2019) provided criteria for defining a condensed plasmoid (CP) as:
“The plasmoid is compressed by a strong z-pinch condition. “Strong” in this sense means, that the internal current is larger than 200 A, the radius of the plasma channel is less than 200 μm and the length of the plasma channel is at least several micrometre. These numbers are based on the computational results of the current modelling. For yet unknown reasons CPs might exist with lower intrinsic currents.
All electrons of the containing atoms (not merely the outer electron shells) are delocalized, i.e. the electrons are all contributing to the current and they can freely move between the atomic nuclei. The delocalization is caused by the small inter-nucleic distance (i.e. less than 10 μm in the case of hydrogen).
The electrons are residing in orbitals, which are at (or near) the quantum-mechanical ground state of the CP. For this to be true, the temperature of the CP must be low enough, that the thermal pressure of the plasma is smaller than the magnetic pressure enforced on the moving electron gas by the Lorentz force.”
   When a current is run through a plasma, the particles in the plasma are pulled toward each other by the Lorentz force, thus the plasma contracts. This contraction is counteracted by the increasing gas pressure of the plasma. This contraction is referred to as the z-pinch (zeta pinch). The z-pinch is a type of plasma confinement system that uses an electric current in the plasma to generate a magnetic field that compresses it, i.e. “pinches” the plasma in a z-axis, oriented perpendicular to the plasma filament direction extending between the electrodes. The plasma filament or “wire” is the interelectrode discharge that occurs between the electrodes and is visible as a spark between the electrodes. The filament is typically not a straight line, but rather an irregular path through the plasma, akin to lightning.
   Jaitner also noted that for a condensed plasmoid to form in an electrical discharge, several conditions appeared crucial, including:
“The current pulse should be very short, i.e. less than a microsecond in duration.
The current needs to be strong enough, i.e. more than hundred amps.
The plasmoid should be cooled, i.e. by running the discharge along a dielectric surface or under water.
Dense matter should be available, which can rapidly feed the forming plasmoid. Typically either the cathode, or the surrounding gas or the dielectric surface will supply the matter that forms the plasmoid.
A magnetic field in parallel to the electric field will steer the electrons in the right direction If the above conditions suffice, the plasmoid will condense. The condensation is promoted by the radial pressure of the magnetic field.”

A condensed plasmoid has a lifetime much longer than that of surface plasmons and the ability to move in an inter-electrode space rather than being bound to the surface of an electrode as the surface plasmons are.

Descriptions of condensed plasmoids of various types in the prior art use different terminology such as “filamentary discharge”, “heavy electrons”, “electric validum” “microplasmoids”, “brush discharge”, or “corona discharge”.

(Nasser, 1971) studied plasmoids and noted that during a high-pressure, non-self-sustained corona discharge (pressure above appr. 10 Torr) the ‘filaments’ (plasma ‘wire’) observed were not electrically neutral and had a negatively charged ‘head’ followed by a ‘tail’ made of a positive ion cloud. This densely charged ‘head’ can be considered a “condensed plasmoid”.

Condensed plasmoids are difficult to study experimentally because they move very quickly in the inter-electrode space. Nevertheless, various researchers have observed condensed plasmoids using high-speed photography and x-ray plates.

(U. D. Kordjev and G. A. Mesyats, 1982) have written a monograph on the subject of condensed plasmoids. They termed the formation of these pseudo-particles as “explosive cathode processes”. A detailed series of photographs were made showing the temporal and spatial formation of the condensed plasmoids extending from a half spherical cathode.

(Raizer, 1987) Also describes condensed plasmoids created by a cathode formed from a micro tip of 0.1 μm radius. Raizier noted the remarkable properties of condensed plasmoids. The current carried during the burst was about 4×10⁹ A cm⁻², during a 5 ns pulse. Raizier notes that the main characteristic of this pseudo-particle is that the number of electrons transported in the condensed plasmoid is greater than the number of atoms in the plasma “blob” by a factor of 10 to 1,000.

A condensed plasmoid thus behaves as a highly charged pseudo-particle that may leave the cathode surface. As Jaitner noted, the condensed plasmoid may ‘screen’ the charges of the positive ions in the plasma. Screening effects in gases, solids, and dense plasmas can increase fusion rates at low reaction energies by several orders of magnitude because screening of the repulsive Coulomb potential by plasmas or target atom electrons increases the probability for ions to tunnel through the Coulomb barrier (Rodney, 1988).

The Kordjev and Mesyats experiments were performed in nitrogen, with the aim to only generate a high-power charge pulse.

Various systems that utilise condensed plasmoids are described by Shoulders in (U.S. Pat. No. 5,018,180, 1991), (U.S. Pat. No. 5,123,039, 1991), (U.S. Pat. No. 5,153,901, 1991), (U.S. Pat. No. 5,054,046, 1990) and (U.S. Pat. No. 5,148,461, 1992). The '461 patent by Shoulders is entitled “Circuits Responsive to and Controlling Charged Particles” and describes experiments in a vacuum and in air. Shoulders termed the condensed plasmoids “heavy electrons” or “electrum validum”. Shoulders also realized that these particles usually form a “ring-like” or “pearl necklace-like” chain.

(Matsumoto, 1993) also discovered the condensed plasmoid effect independently of Shoulders and Mesyats. Matsumoto used underwater sparking at about 70 Volts. Matsumoto observed the presence of the same necklace-shaped traces as Shoulders, as well as transmutation of elements and an excess energy output. Transmutations were also observed during underwater sparking experiments.

However, this spark-related transmutation in hydrogen gas was discovered much earlier by (Thomson, 1913) and (Collie, 1914) who carried out their experiments in hydrogen with 12-inch interelectrode discharges. Emission spectrum analysis was used to identify helium and neon resulting from the transmutation of hydrogen.

The aforementioned references establish the following causal connections:

Inter-electrode discharges (sparks) in a plasma generate dense, negatively charged pseudo-particles, herein termed ‘condensed plasmoids’.

The condensed plasmoids represent a high-mass, highly-charge (negative), pseudo-particle.

Further prior art includes the inventions described in the following patents and publications.

(U.S. Pat. No. 4,454,850, 1979) by Horvath describes the use of hydrogen and compressed hydrogen as fuel and 40 kV sparks.

(WO Patent No. 1994/009560, 1994) Correa et. al. used parallel plates in a discharge tube with pulsed arc discharges. However, severe erosion of the cathode occurred which meant the system was not sustainable.

(U.S. Pat. No. 4,661,747, 1985) by Gray describes a method using sparks generated by an inductive ‘kick’. The Gray cathode was a metal wire mesh but the plasma composition was undisclosed. The output was also a short electric pulse harvested by an inductive load. An inductive load (electric AC motor) was driven by the pulses.

(U.S. Pat. No. 3,670,494, 1968) by Papp used high-voltage sparks between conical electrodes. The plasma contained water vapor and inert gases. The energy released during a sparking/explosion was used in an analogous way to an internal combustion engine.

The aforementioned inventors had a practical, phenomenological insight for the physics behind their inventions, but none of the inventions appeared to be able to provide sustained, reliable production of condensed plasmoids. Common problems included irregular or unreliable production, damage or deterioration to the electrodes or carbon build-up on electrodes. Condensed plasmoid production efficiency is greatly reduced when the electrodes become damaged and much energy is lost in EM radiation and heat.

It was nevertheless found in the prior art that these condensed plasmoids may be used to induce nuclear fusion and transmutation of elements. The basis for these theories is that condensed plasmoids can screen the Coulomb barrier so that fusion of various particles may occur.

Jaitner mentioned in his paper, “A well-designed LENR reactor would probably attempt to promote the self-sustained CP existence (or growth), because the creation of new CPs would produce more unwanted x-rays and would consume more input energy. In order to stop a LENR reactor, one has to stop creating new CPs and one has to remove the conditions required for self-sustained growth. One could even attempt to generate electrical energy directly from LENR, which would remove some of the complexities and expenses involved by converting heat to electricity.”

The production of condensed plasmoids is thus an important tool in the study of quantum phenomena and nuclear reactions in plasma.

Such prior art Low Energy Nuclear Reaction (LENR) systems generally involve the use of a pair of electrodes positioned with an interelectrode gap spanning a discharge chamber containing a gas or liquid. The cathodes in many examples are typically formed of a deuterium saturated lattice of palladium or other metal.

The prior art LENR experiments involving discharge tubes have been carried out by a range of investigators but have generally only achieved minimal net energy output, in the form of heat, and often with the destruction of the cathode. Heat output necessarily requires conventional heat-to-electricity conversion methods with accompanying energy loss. The efficiency losses in the heat-to-electricity conversion and low net-energy output of the existing LENR systems have meant that using net energy output from such reactors has not been viable as a useful energy source.

The destruction of the cathode is mentioned in the background art section of (US Patent No. 20190122774, 2018) by Godes. The Godes system used a palladium lattice-core saturated with hydrogen isotopes which is then bombarded with phonons. There are resultant fusion reactions that produce large amounts of heat that can be harvested for energy. Godes terms this process a Controlled Electron Capture Reaction (CECR).

The underlying physics explaining this transmutation phenomenon is encapsulated in the Widom-Larson theory which potentially explains the excess energy produced by many of the LENR fusion experiments conducted over the last 40 years. A summary and explanation can be found at

In summary, according to the theory, a metal (palladium, for example) is saturated with hydrogen (e.g. in bath of water subject to electrolysis). When the metal is saturated, the hydrogen's protons collect in groups on top of the electrons on the metal's surface.

The protons quantum-mechanically entangle with each other to form “heavy” protons. The surface electrons will similarly behave as “heavy” electrons. An energy source, e.g. laser, gives the heavy proton and heavy electron enough energy to force a tiny number of the entangled electrons and protons to merge into neutrons.

Those neutrons are then captured by nearby atoms in the metal by neutron-proton fusion, emitting energy in the form of gamma rays in the process. The heavy electron captures those gamma rays and reradiates them as infrared. Whilst this fusion occurs and excess energy produced, the reaction destroys the site on the metal where it took place, forming a tiny crater in the metal.

Another prior art example is the controversial Martin Fleischmann and Stanley Pons studies in the 1980s that involved a method of ‘reducing’ the Coulomb barrier to enable what has since been termed ‘cold’ fusion.

Fleishmann and Pons believed they had observed nuclear reaction by-products and a significant amount of heat generated by a small tabletop experiment involving electrolysis of heavy water on the surface of palladium electrodes. The explanation presented was that hydrogen and its isotopes could be absorbed in certain solids, such as palladium, at high densities. The absorption of hydrogen creates a high partial pressure, reducing the average separation of hydrogen isotopes and thus lowering the Coulomb barrier. Another explanation was that electron screening of the positive hydrogen nuclei in the palladium lattice was sufficient for lowering the Coulomb barrier.

The Fleischmann-Pons findings initially received significant attention. However, subsequent studies and review resulted in their experiments being deemed not to have produced excess energy via fusion. There is still debate in the scientific community as to what was occurring in the Fleischmann-Pons experiments. The Widom-Larson theory mentioned above seems to be the best explanation of the Fleischmann-Pons findings and explains why it was difficult to replicate the results.

Another method to reduce the Coulombic barrier employs electron screening in a solid matrix and an example is described in (US Patent No. 2005-0129160, 2003) by Indech. Indech appears to describe screening of the Coulomb barrier via electron screening of positively-charged repulsive forces between two deuterons located near the tip of an electrode's microscopic cone structure (referred to as “atomically sharp”) when electrons concentrate at the top of the cone structure due to an applied potential.

(Chen, Vol. 10 No. 1, January 2020) describes use of a neutron ‘beam’ theory of achieving low-temperature fusion by using a neutron source in which a single energy electron beam collides with a single energy bare nucleus beam, such as a deuteron, to produce a single energy neutron. These neutrons irradiate target nuclei and are absorbed by the target nuclei, so that nuclear energy is released. The Chen system however requires large input energies in order to separate neutrons from constituent atoms.

Another form of known ‘cold’ fusion is Muon-catalyzed fusion (abbreviated as μCF) which describes a process allowing nuclear fusion to take place at temperatures significantly lower than the temperatures required for thermonuclear fusion, even at room temperature or lower. It is one of the few known ways of catalyzing nuclear fusion reactions.

Muons are unstable negatively charged subatomic particles which are similar to electrons but 207 times more massive. A muon (−μ) may be injected into a mixture of deuterium and tritium and is captured by one of the two hydrogen isotopes in the mixture, forming either atomic D+−μ or T+−μ, with the atom now in an excited state. The excited atom relaxes to the ground state through a cascade collision process, in which the muon may be transferred from a deuteron to a triton or vice versa. It is also possible that a muonic molecule (D+−μ−T+) will be formed. Fusion takes place almost immediately once a muonic molecule forms, releasing the muon in the mixture to be captured again by a deuterium or tritium nucleus and allowing the process to continue.

The muon effectively acts as a form of catalyst to ‘screen’ the Coulomb barrier (i.e. reducing the electrostatic repulsion between two nuclei. The nuclei are thereby drawn together. Because the nuclei are so close, the strong nuclear force is able to overcome the Coulomb repulsion force and both nuclei fuse together. The catalytic muon is normally released after this reaction and part of the original mass of both nuclei is released as energetic particles.

The μCF evolution using a deuterium (d), tritium (t) mixture proceeds in the following stages: dp or tμ formation (10⁻¹¹ sec)->muon transfer (<10⁻⁸ sec)->dtμ molecule formation (<10⁻⁸ sec)->intramolecular nuclear fusion (10⁻¹¹ sec)->release muon with energy 10 keV. The process continues during the lifetime of a muon (2.2×10⁻⁶ sec). The period of one cycle is approximately 2×10⁻⁸ sec. Muons decay rapidly (in about 2×10⁻⁶ seconds) due to their unstable nature and so not many fusion reactions occur.

Each catalyzed fusion reaction yields 17.6 MeV between the deuterium and tritium nuclei, and during several catalytic events the total energy release is about 2000 MeV. The rest mass of a muon is 106 MeV, thus the energy balance appears positive. However, the accelerators making muons are not 100% efficient and thus it takes about 8000 MeV to make muons. The small number of reactions and therefore energy released is thus too small relative to the energy requirements to make μCF viable.

Tritium is also very expensive and generating tritium via μCF to make a self-sustaining process does not appear commercially possible at this point. It thus appears that the Muon “manufacturing” efficiency cannot be further refined. Moreover, the resultant heat generated in the liquid deuterium-tritium mixture is not useful in thermal engines which require a larger temperature gradient to operate. Thus, μCF is at this point not technically viable for net-positive energy generation.

It is thus evident from the prior art that there are many approaches to Low Energy Nuclear (LENR) fusion that have varying degrees of success but prove that further research is desirable. As part of this research, the formation, and use, of condensed plasmoids appears a highly promising technique.

Furthermore, it would be highly advantageous to develop a method and apparatus for catalyzing fusion reactions using condensed plasmoids, which may act as a much more economical fusion catalyst than muons.

It is thus an object of the present invention to produce an apparatus and method for generating condensed plasmoids.

Another object of the present invention is to be able to control the characteristics of condensed plasmoids through modification of apparatus parameters.

It is an object of the present invention to address the foregoing problems or at least to provide the public with a useful choice.

All references, including any patents or patent applications cited in this specification are hereby incorporated by reference. No admission is made that any reference constitutes prior art. The discussion of the references states what their authors assert, and the applicants reserve the right to challenge the accuracy and pertinency of the cited documents. It will be clearly understood that, although a number of prior art publications are referred to herein, this reference does not constitute an admission that any of these documents form part of the common general knowledge in the art, in New Zealand or in any other country.

It is acknowledged that the term ‘comprise’ may, under varying jurisdictions, be attributed with either an exclusive or an inclusive meaning. For the purpose of this specification, and unless otherwise noted, the term ‘comprise’ shall have an inclusive meaning—i.e. that it will be taken to mean an inclusion of not only the listed components it directly references, but also other non-specified components or elements. This rationale will also be used when the term ‘comprised’ or ‘comprising’ is used in relation to one or more steps in a method or process. Further aspects and advantages of the present invention will become apparent from the ensuing description which is given by way of example only.

### DISCLOSURE OF INVENTION

### Terms Used in this Specification

A charge “cluster” herein refers to a discrete group of charges constrained together.

A “plasmoid” herein refers to a coherent structure of plasma and magnetic fields.

A “condensed plasmoid” herein refers to a plasmoid formed from a cluster of electrons.

A “reactor” herein refers to a device or apparatus for containing a reactant gas and producing plasmoids therein.

A “collection” of clusters or condensed plasmoids refers to a group of multiple clusters or condensed plasmoids that are constrained together.

“Cathode” refers to a negatively charged electrode. “Anode” refers to an electrode having a more positive charge than the Cathode when preceding a discharge between the cathode and anode.

As used herein the term “catalyst” with respect to nuclear fusion refers to a thing that causes or enables nuclear reactions to occur under different conditions than would otherwise be possible without such a catalyst. Similarly, the terms “catalyze” and “catalyzing” refer to the act of enabling a reaction to occur by acting as a catalyst.

According to one aspect of the present invention there is provided an apparatus for generating interelectrode discharges, the apparatus including a reactor including:
a chamber for containing a reactant gas;
a pair of electrodes at least partially extending into the chamber, the electrodes including at least one cathode and at least one anode;
an interelectrode gap formed between the electrodes;
wherein the electrodes are connectable to an electrical circuit, the electrical circuit including a power supply for applying an electric potential difference between the electrodes to form a plasma through which an interelectrode discharge traverses the interelectrode gap, and
characterised in that the cathode has an electron discharge material.

Preferably, the apparatus is for generating condensed plasmoids, wherein in use the electron discharge material emits clusters of electrons that form condensed plasmoids.

According to a second aspect of the present invention there is provided a reactor for generating condensed plasmoids, the reactor including:
a chamber for containing a reactant gas;
a pair of electrodes at least partially extending into the chamber, the electrodes including at least one cathode and at least one anode;
an interelectrode gap formed between the electrodes;
wherein the electrodes are connectable to an electrical circuit, the electrical circuit including a power supply for applying an electric potential difference between the electrodes to form a plasma through which an interelectrode discharge traverses the interelectrode gap, and
characterised in that the cathode has an electron discharge material from which clusters of electrons may emit to form condensed plasmoids.

Preferably, the reactant gas is capable of being ionised by the electric potential difference between the electrodes to thereby form the plasma.

Preferably, the electron discharge material is a material capable of generating spin-polarised electron clusters from an electric current passed through the electron discharge material.

Preferably, the electron discharge material includes a semiconductor material.

Preferably, an exterior surface of at least part of the cathode is formed from the semiconductor material.

The electron discharge material may be formed as at least one of:
an outer surface of a cathode constructed from the electron discharge material;
a layer or coating on a conductive substrate of the cathode, and/or
a surface treatment of a conductive substrate of the cathode.

Preferably, the cathode substrate within the reactor chamber is at least partially covered by the semiconductor material and more preferably, is completely covered by the semiconductor material such that the substrate is not exposed directly to the reactant gas.

In one embodiment, it is sufficient for the cathode substrate near the interelectrode gap to be completely covered by the semiconductor material while distal portions of the cathode may not need to be covered.

A said semiconductor material preferably has a thickness in the range of 1 to 100 μm.

In one embodiment, the semiconductor material is doped to alter the conductivity.

Preferably, the apparatus generates at least one condensed plasmoid with the interelectrode discharge.

Preferably, the clusters of electrons are spin-polarised.

Preferably, the condensed plasmoid includes a cluster of electrons having the same electron spin-state.

Preferably, the electron discharge material has inversion asymmetry.

Preferably, the electron discharge material has chirality.

Preferably, the apparatus includes the electric circuit.

Preferably, at least part of the semiconductor material includes an amorphous semiconductor.

In a further embodiment, the semiconductor material includes a chalcogenide glassy semiconductor material.

Preferably, the cathode is shaped and constructed such that when the electric potential is applied, an electric field generated within the cathode is aligned substantially coincident or parallel with an axis extending through a direct traverse of the interelectrode gap.

Preferably, the cathode is shaped and constructed such that when the electric potential is applied, an internal current is generated within the cathode that is aligned substantially coincident or parallel with an axis extending through a direct traverse of the interelectrode gap.

Preferably, the anode is shaped and constructed such that when the electric potential is applied, the generated electric field within the anode is aligned substantially coincident with, or parallel to an axis extending through a direct traverse of the interelectrode gap.

Preferably, the anode is shaped and constructed such that when the electric potential is applied, an internal current is generated within the anode that is aligned substantially coincident or parallel with an axis extending through a direct traverse of the interelectrode gap.

Preferably, the cathode and/or the anode is shaped and constructed such that when the electric potential is applied, an internal current is generated within the electron discharge material, the current aligned substantially coincident or parallel with an axis extending through a direct traverse of the interelectrode gap.

Preferably, at least a portion of the electron discharge material surface located proximal the interelectrode gap is aligned substantially coincident or parallel with an axis extending through a direct traverse of the interelectrode gap.

A number of apparatus parameters affect the formation of the condensed plasmoids, including the semiconductor material, electrode shape and material, inter-electrode distance, chamber pressure and characteristics of the electrical potential applied. Each of these parameters will be explained in detail separately.

A condensed plasmoid is considered herein to be a plasmoid formed from a cluster of electrons. Preferably, a condensed plasmoid is formed from a spin-polarised cluster of electrons, i.e. with a total sum of the spin of the constituent electrons in the cluster being non-zero.

To generate a plasmoid it is necessary to provide an electric potential between the electrodes that is sufficient for electron emission from the cathode and to create the conditions necessary for the electrons to cluster together.

Condensed plasmoids are generated when electrons emit from the cathode in clusters. These clusters are formed in the surface of the cathode and when emitted become condensed plasmoids.

The cathode construction is thus particularly important for condensed plasmoid formation as it defines the propagation of charge clusters in the cathode surface. It is only when a charge cluster is emitted from the cathode into the plasma, that they are termed a ‘condensed plasmoid’ herein, though the cluster and condensed plasmoid are both formed from a cluster of electrons.

It's desirable to bind many condensed plasmoids together to form a ‘collection’, which has a charge and mass equal to the sum of the constituent condensed plasmoids and is thus much higher than a single condensed plasmoid. This comparatively high electrical charge and mass can thus be used to accelerate positive ions (e.g. deuteron or triton) in the reactant gas toward the densely charged collection. If the acceleration is sufficient to bring the positive particle into sufficient proximity with an electron of a condensed plasmoid then fusion will occur, resulting in a neutron and neutrino.

Charge clusters of the same charge polarity are naturally electrostatically repulsive, which forces the clusters apart. This effect has led to the assumption in the prior art that it is impossible to bind the clusters. However, each charge cluster also has a magnetic moment and dipole depending on the spin-polarisation of the cluster, which in turn depends on the spin-states of the constituent electrons. Thus, clusters with the same spin-polarisation will be mutually magnetically repulsive while those of opposite spin-state will be magnetically attractive. A stable collection of condensed plasmoids may therefore be formed if there are clusters with both spin-up and spin-down polarisation near enough to each other to magnetically attract and overcome the corresponding electrostatic repulsion.

It is therefore desirable to produce clusters of different spin-polarization. Preferably, an equal number of spin-up polarized and spin-down polarized clusters will maximise the utilisation of the clusters produced.

A charge cluster is considered ‘spin-polarized’ when the total spin of the electrons in the cluster is non-zero. Preferably, all the electrons in the cluster have the same spin-state. However, a cluster may still be spin-polarized if there is any difference in the number of electrons in each spin-state.

As evident in the prior art, metal or conductive electrodes can produce some electron clusters and condensed plasmoids. However, the prior art inventors were not aware of the way condensed plasmoids formed the stable ring-like structures they observed. The prior art sought to develop apparatus and methods to concentrate the discharge on a small point to achieve the concentrated cluster formation. This method reduces the electric potential needed for a discharge and plasma formation but results in few condensed plasmoid collections formed, and often destruction of the cathode. The prior art thus did not endeavour to find a way to improve the spin-polarization of clusters.

Spin-polarisation is a phenomenon that has been investigated extensively for use in spintronics applications such as data storage. Spin-polarised electron clusters form in a surface by utilising the Spin Hall Effect (SHE). The Spin Hall Effect is a transport phenomenon determined by Russian physicists Mikhail I. Dyakonov and Vladimir I. Perel in 1971. The SHE consists of the appearance of spin-polarised electrons on the lateral surfaces of an electric current-carrying sample, the spin polarisation (‘spin state’ or ‘spin orientation’) being opposite on the opposing boundaries.

The present invention may utilise these same spin-polarization properties but using a semiconductor material as the electron discharge material. Semiconductors are better able to generate spin-polarized charge clusters than conductors.

Thus, by utilising a cathode having a surface of semiconductor material, the electron clusters in the cathode become spin-polarized, with adjacent clusters being oppositely polarized. When emitted as ‘condensed plasmoids’, the clusters retain their spin-polarization and bind together to form collections of condensed plasmoids. The electrostatic repulsion is balanced by the magnetic attraction in these collections and so they can form relatively ‘stable’ structures—compared to unbound clusters. Metal or conductive electrodes form mostly clusters with the same spin-polarisation, or no polarisation at all and therefore are inefficient for condensed plasmoid collection generation as they only rarely form collections of clusters.

We will now discuss the interelectrode discharge. An interelectrode discharge occurs from the cathode to the anode when the electric potential reaches a threshold value determined by the following parameters:
interelectrode gap, i.e. the distance the interelectrode discharge must traverse;
electrode surface material proximal the interelectrode gap;
reactant gas type;
electrode shape proximal the interelectrode gap.

The interelectrode discharge may be considered to have a ‘longitudinal’ direction orientated to span the interelectrode gap between the cathode to the anode. It will be appreciated that the discharge may not form a straight line along an axis, (i.e. a straight line between directly opposing portions of the electrodes) and may fluctuate and deviate from a straight axis spanning the interelectrode gap due to variation in the ionised gas forming the discharge path. The variation is due to the natural variability in the reactant gas concentration and pressure which causes an irregular ionisation path.

The semiconductor is preferably chosen such that the spin-polarised electron clusters are formed as a distribution over the semiconductor when an electric potential is applied between the electrodes. The electron spin distribution preferably includes clustering of electrons in clusters with the same, or at least majority the same, spin state, i.e. there are spin-polarised clusters.

Preferably, the internal current in the cathode includes adjacent areas of electric current, having opposing polarity spin-polarised clusters with respective ‘up’ and ‘down’ spin states.

Preferably, for a cathode with an internal current aligned on a ‘longitudinal’ direction, the internal current is distributed into laterally adjacent currents having oppositely spin-polarised currents.

The semiconductor properties for use as a semiconductor material in the present invention are selected to define how effective and efficient the apparatus is at generating condensed plasmoids with such desired properties.

Preferably, the semiconductor material includes a chalcogenide material and more preferably a glassy, disordered, homogenous and isotropic chalcogenide material. Such a semiconductor material may thus yield the spin-polarised electric current ideal for spin-polarised condensed plasmoid formation.

The efficiency of the spin-polarised current generation in the cathode defines how effective the apparatus will be in generating condensed plasmoids. High efficiency can be achieved using a semiconductor material formed from such a chalcogenide semiconductor material.

The semiconductor material preferably does not have inversion symmetry, i.e., it has inversion asymmetry. Glassy semiconductors such as aluminium oxide or lead sulphite for example, may satisfy this criterion.

Preferably, a majority of the atoms of the semiconductor material at rest have the same spin orientation and more preferably, all the atoms have the same spin orientation. This spin-alignment makes it possible for full spin coherence and spin alignment.

Preferably, the semiconductor material has high carrier mobility i.e., as many free electrons as possible.

Preferably, the semiconductor material has low spin scattering at a surface-plasma interface. This property is important as the spin-polarised electron clusters are destroyed or disrupted if the scattering is large. Electrons cross the surface-plasma interface in a very brief duration i.e. in less than a femtosecond. The semiconductor material quality, preparation and degradation all influence the degree of spin scattering and therefore the efficiency of condensed plasmoid formation.

The dielectric constant of the semiconductor material also affects the spin-polarised electron cluster formation. The higher the dielectric constant, the more likely that the spin-polarised electron clusters are formed. In contrast, in pure metal cathodes with infinite dielectric constant, most of the electric current will form dissipative plasma and minimal spin-polarised electron clusters are formed. Thus, pure metal cathodes are not desirable for the present invention.

The semiconductor material is thus preferably a chalcogenide material. Chalcogenide materials are a very poor conductor up to the opening threshold, thus making it possible for spin-polarisation accumulation to occur. Above the opening threshold the resistance is suddenly reduced, allowing the spin-polarised clusters to leave the cathode through the plasma generated by the interelectrode discharge.

The semiconductor material preferably contains a metal of high nuclear spin, e.g. bismuth, indium and niobium. Alternatively, although non-optimal, other metals may be used, such as aluminium, vanadium, tantalum and the like, which still have a non-zero nuclear spin.

The following table shows potential elements and their nuclear spins. Note that spin will depend on the specific isotope as well.

| Element | Nuclear spin |
|---|---|
| Nb, In, Bi, At | 9/2 |
| Sc, V, Co, Ta, Ho, La, Sb | 7/2 |
| Al, Mn, Sb, Pr, Re | 5/2 |
| Cu, Ga, As, Ir | 3/2 |
| Ag, Tl, Rn | 1/2 |

The semiconductor material is thus preferably a chalcogenide of one of the aforementioned metals. Preferably, the semiconductor material is a chalcogenide of a metal of nuclear spin of at least 5/2.

Although various semiconductor materials may be utilised, it will be appreciated that some materials have characteristics that may make them less desirable. By way of example, Niobium oxide or niobium sulphate materials may be efficient, safe, durable and withstand high temperature. However, they are expensive to manufacture. In contrast, bismuth oxide is a relatively inexpensive semiconductor material but has a relatively low melting point and would thus prove less durable. Other materials may be more or less expensive, have safety, radioactivity or toxicity considerations or may be rare.

On balancing the considerations or cost, durability, availability and efficiency, the semiconductor material preferably includes a metal oxide or metal sulphide. In one preferred embodiment, the semiconductor material includes an oxide of silver on a niobium substrate. The silver may be deposited as a thin coating on the niobium via electrolysis and then the silver oxidised (or alternatively sulphated), thereby forming the semiconductor material.

The substrate metal preferably has a high nuclear spin, as per the above table. However, in one embodiment the substrate metal may be an alloy, including other elements. One such alloy may be a niobium and barium titanate (BaTi) alloy. The semiconductor material is preferably an oxidised or sulphated silver coating as previously mentioned.

BaTi is a ferroelectric, pyroelectric, and piezoelectric ceramic material and is often used in capacitors, electromechanical transducers and nonlinear optics. The use of BaTi in the substrate can reduce the input voltage required at the cathode and thereby reduce the capacity of the power supply needed. The alloy may be produced using various techniques but as BaTiO₃ is a ceramic powder, one technique that is suitable is fuse deposition modelling (FDM), a form of 3D printing.

In another embodiment, the semiconductor material includes aluminium oxide. Aluminium oxide is useful as (relative to many of the materials mentioned above) it:
is relatively inexpensive to manufacture,
is relatively safe
is relatively durable
has a relatively high melting temperature.

The aluminium oxide may be formed as a coating of an aluminium substrate by oxidising the aluminium substrate, thereby providing an inexpensive process for generating an electrode with a conductive substrate and semiconductor exterior.

The semiconductor material preferably has a low thermal expansion gradient, to prevent the deformation of the semiconductor material under rapid electric potential loading and unloading.

The semiconductor material preferably has a high heat conduction coefficient to avoid melting as heat increases.

The semiconductor material preferably has a high tensile strength to avoid local cracking in case of heat expansion between the semiconductor material and any core cathode material.

The semiconductor material preferably has a high heat capacity to store heat, thereby avoiding melting and surface erosion.

The semiconductor material preferably has a high melting/softening temperature to avoid melting and surface erosion.

The semiconductor material may be formed as a layer, coating or surface treatment on a metal or other conductive substrate. Preferably, the semiconductor material is formed as a surface layer of less than 100 micrometres. In alternative embodiments, the cathode may be formed mostly or entirely from a semiconductor material. However, a cathode constructed entirely from semiconductor will raise the electric potential threshold required for interelectrode discharge relative to a conductive electrode of the same size and shape and is thus likely not to be as efficient.

The semiconductor material has a thickness preferably between 0.05-0.5 mm and more preferably about 0.1 mm.

Preferably, the entirety, or at least majority, of the outer surface of the cathode exposed to the chamber is formed from the semiconductor material.

The electrodes in the present disclosure are preferably formed such that each electrode is provided with a terminal periphery proximal the inter-electrode gap. Preferably, the terminal peripheries of both electrodes mirror each other, the interelectrode gap being formed therebetween.

Preferably, the terminal periphery of the cathode is formed from the semiconductor material.

Preferably, the terminal periphery of the anode is formed from the semiconductor material.

It is desirable to maximise the number of spin-polarised electron clusters to form on the semiconductor surface as this effect ensures a high efficiency of condensed plasmoid formation. To this end, the nature of the surface emitting the electrons is also important for efficient spin-polarised electron cluster formation.

The electron discharge material is preferably an inhomogeneous surface, providing at least some pathways for electron clusters to pass therethrough. As used herein, the term ‘inhomogeneous’, with respect to a surface, means that the surface is not the same at each point over its extent, e.g. a porous surface is inhomogeneous as the pores are different to the areas surrounding them. In contrast, a continuous, smooth surface is considered ‘homogenous’.

Preferably, the electron discharge material is a porous surface, providing pathways (‘pores’) for electron clusters to pass therethrough.

It would be possible to generate condensed plasmoids using an electron discharge material coating a conductive substrate, where the electron discharge material is formed with small tubular pathways, e.g. ‘pores’, of diameter equal to the size of an optimal electron cluster. This would thus provide a surface that is effectively ‘porous’ to the electron clusters, enabling efficient emission while maintaining the ordered state of spin polarisation. However, manufacturing such a surface appears to be beyond current manufacturing techniques.

Therefore, to improve efficiency of condensed plasmoid generation, given readily available materials, the semiconductor material preferably includes a chalcogenide. As mentioned previously, such a chalcogenide electron discharge material naturally provides a surface with a fine microstructure of cavities, cracks, grooves and other irregularities. Thus, although the electron discharge material may cover the electrode on a ‘macro’ scale, the semiconductor material is effectively ‘porous’ at an atomic scale and thus permits the passage of spin-polarised electrons from the underlying substrate. This effect enables the spin-polarised electron clusters to form on the semiconductor surface. Thus, maximising this ‘porous’ effect ensures a high efficiency of condensed plasmoid formation.

According to one aspect, there is provided a method of forming the semiconductor material on a said electrode, the method including anodization or oxidation of a metal to form a chalcogenide surface layer on a metal substrate.

Anodization or oxidation are inexpensive techniques for forming the semiconductor material on the electrodes and provide a durable semiconducting layer. The deposition time, electrolyte pH, electrolyte chemistry (acid or alkaline), bath temperature and current density all affect the semiconductor material topology.

In most other applications the anodization or oxidation layer is desired to be as smooth as possible and so smoothing treatments are applied. However, smoothing of the surface reduces the irregularity of the micro-structure of the surface and thus creates a more ‘homogenous’ surface. This homogeneity reduces the efficiency of the spin-polarised electron cluster formation as there are no pathways for the electron clusters to emit. Therefore, while providing a hard durable surface, readily available commercially anodized surfaces are undesirable as they do not provide the desired inhomogeneous structure.

To improve the inhomogeneity, it is possible to increase the number of ‘irregularities’ or ‘surface roughness’. In one embodiment, the aforementioned anodization method includes varying current density during the anodization or oxidation.

Preferably, the current density is increased after a predetermined period in which a thin layer is formed. As the current density is increased, small oxygen bubbles appear on the anodized surface, inhibiting the oxide layer formation, thus forming a ‘crater’ or ‘pore’ at the bubble location.

It will thus now be apparent that any coating that ‘smooths’ the surface (such as oils or other deposits) will be detrimental to the efficiency of the apparatus. Therefore, the semiconductor material is preferably kept clean and free from oils or other smoothing deposits.

Many solid and liquid materials can emit electrons in a CFE regime if a sufficiently high electric field is applied, i.e. above the ‘discharge threshold’. Thus, in order for an electric field emission to occur from the cathode, a sufficient voltage must be applied depending on the shape of the emitting portion. A cuspate (i.e., ‘sharper’) emitting portion requires less voltage for the emission to occur as the electrons are concentrated in smaller areas, thus generating a higher ‘effective’ electrical potential. It is therefore preferable to have small opposing areas of the electrodes proximal the interelectrode gap, relative to the overall electrode size.

The cathode thus preferably includes a cuspate terminal periphery.

Preferably, the cathode and/or the anode terminal periphery is laterally cuspate about at least one axis orthogonal to a span of the interelectrode gap.

A cathode with a sharp singular point would require the lowest voltage for emission to occur. However, such a sharp point ensures that the discharge occurs from the same point repeatedly, this can lead to overheating and damage to that point.

The terminal periphery(s) of the present disclosure is thus preferably elongate. Preferably, the terminal periphery(s) has a length of at least 10 mm.

In one embodiment, the electrodes may be cylindrical with a circular terminal end proximal the interelectrode gap, wherein the terminal periphery is formed on the circular terminal end and the terminal periphery length is approximately equal to the circumference of said terminal end.

It will be appreciated that provided the electrodes maintain a substantially constant interelectrode gap separation between terminal peripheries and are configured with a substantially identical terminal periphery shape, orientation, and dimensions proximal and orthogonal to the interelectrode gap, then the shape of the terminal peripheries of the electrodes need not be constrained to a particular shape or size.

Reference herein is made to the potential shape and size of the electrodes and components. It should be appreciated that, while ideally the electrodes have the shape or size stated, the apparatus will still likely function with minor variations or inconstancies, e.g. reference to a circular cross-section should not be seen to be limited to a perfectly circular cross-section and variation due to manufacturing capability and tolerances are expected.

The interelectrode gap preferably has the same separation distance between all directly opposing portions of the electrodes, and preferably the same separation distance between the terminal peripheries.

A constant interelectrode gap is important to prevent the inter-electrode discharge “anchoring” in the same location, as this anchoring may result in overheating at the anchoring point and cause deterioration of the electrode.

The interelectrode gap distance may be varied depending on the application, input voltage and apparatus characteristics. However, an inter-electrode gap of 1-2 mm has been found to be sufficient for condensed plasmoid generation under a 1-3 kV input potential and a chamber pressure of below 600 mbar.

It is possible to utilise very small gaps or higher voltages, though this necessarily reduces the allowable tolerances in uniformity and may require more expensive componentry, i.e. it is expensive to manufacture apparatus with a constant separation interelectrode gap where there is a very small interelectrode gap distance, or more robust capacitors and other electrical circuitry are required in the case of much higher voltages.

Preferably, the terminal periphery of the cathode is formed by the cathode semiconductor material.

Preferably, the terminal periphery of the anode is formed by the anode semiconductor material.

In one embodiment, the electrodes include portions formed as hollow cylinders, separated axially to provide an interelectrode gap formed by the space between circular terminal peripheries of the opposing cylinders. Electrodes with elliptical cross-sections may also be utilised. However, cylinders are easier to manufacture and align than an electrode with an elliptical cross-section.

Preferably, the cylinders have the same diameter and/or are aligned coaxially.

A larger surface area of the semiconductor material generates a greater quantity of spin-polarised clusters for a given potential difference applied. Therefore, it is preferable to maximise the semiconductor material area for a given size reactor.

Preferably, the cylinders are thus axially elongate.

Preferably, the semiconductor material of the cathode is formed as a radially outer semiconductor surface on the cathode.

Similarly, a semiconductor material of the anode may be formed as a radially outer semiconductor surface on the anode.

The electrodes are preferably formed as hollow cylindrical electrodes.

The spin-polarised charge clusters dissipate when in contact with a conductive material and thus it is preferable that there are no conductive components exposed to the plasma.

Thus, preferably, the radially inner surfaces of the hollow electrodes are formed from a semiconductor material.

The inner semiconductor material surface of the cathode may also act to form spin-polarised clusters of electrons in the same manner as the outer semiconductor surface.

Preferably, both electrodes are connected to the electrical circuit.

At least one electrode is preferably connected to the electrical circuit at an electrical connector end, distal to the interelectrode gap.

In prior art plasma discharge apparatus, the electrodes are normally formed as plates or similar and aligned in parallel planes. Thus, the electric current through the interelectrode gap is oriented non-parallel to the electrode surface. In contrast, the cylindrical electrodes as aforementioned provide an electric current through the cathode that is aligned parallel with the semiconductor material surfaces and approximately parallel with the major direction of interelectrode discharge between the electrodes. This alignment is important for the efficient generation of condensed plasmoids as it results in the most efficient generation of spin-polarised clusters, due to the skin effect mentioned previously, which pushes electrons to the surface of the material perpendicularly to the current direction.

A said semiconductor material is preferably formed from a layer with a thickness less than half the radius of the corresponding electrode.

The diameter of the electrodes may be varied depending on the apparatus size and other parameters but in one preferred embodiment is in the order of 5-50 mm. The electrodes have a wall thickness preferably in the range of 0.5-2 mm.

The axial lengths of the electrodes may be varied depending on the application and manufacturing capabilities. Variations in electrode construction may yield greater condensed plasmoid generation efficiency.

The anode's purpose is somewhat different to the cathode and so it may be possible to construct an effective anode without exactly the same requirements as the cathode.

The anode preferably also includes a semiconductor material.

The anode semiconductor material is preferably formed from a semiconductor material layer located on a substrate.

The anode substrate is preferably electrically conductive. The anode substrate is preferably electrically connectable to the electrical circuit.

Preferably, the anode substrate within the reactor chamber is at least partially covered by the semiconductor material and more preferably, is completely covered by the semiconductor material such that the substrate is not exposed directly to the reactant gas.

In one embodiment, it may be sufficient for the anode substrate near the interelectrode gap to be completely covered by the semiconductor material while distal portions of the anode substrate may not need to be covered.

The anode semiconductor material preferably includes a portion located between the anode substrate and the interelectrode gap. The anode semiconductor material ensures the condensed plasmoids in the interelectrode gap don't directly contact an otherwise metal (conductive) anode and dissipate. Condensed plasmoids will dissipate when touching a grounded metal surface.

The anode semiconductor material also acts as a resistive barrier, limiting the current of the inter-electrode discharge.

The anode semiconductor material resistivity is a parameter affecting the discharge through the anode, e.g. an anode semiconductor material with lower resistivity results in a discharge of higher current. The anode and anode semiconductor material may therefore be varied to suit the application, which may have particular voltage or current output requirements.

The electrical circuit preferably includes an electric pulse generation unit connected to the power supply and for applying a pulsed electrical potential difference between the cathode and the anode.

The electric pulse generation unit preferably applies electric potential to the electrodes in pulses having a period less than the spin ‘relaxation time’ of the cathode. In some embodiments, (e.g. with an aluminium oxide electron discharge material) the electric pulses are preferably less than 10 microseconds and more preferably about 2 microseconds.

The spin ‘relaxation time’ refers to the time taken for the spin-polarised charge clusters in the semiconductor material to dissipate into a non-polarised state. The electric pulse generation unit preferably applies pulses of about one microsecond in duration.

The short pulse duration of the electric pulse generation unit is important for ensuring that interelectrode discharges occur only when the cathode has the charge clusters in the spin-polarised state.

The ordered spin states are accumulated in the semiconductor material only within a short ‘spin accumulation’ period. This is the consequence of a number of effects and is affected by various parameters. For example, thermal noise at room temperature or higher will reduce the potential ‘coherence’ or ‘spin accumulation’ period.

The short electric pulses produce a ‘skin effect’ through the current-carrying cathode, resulting in forcing the spin-polarised electrons to an outer surface of the cathode. As is known in the art, the ‘skin effect’ is the tendency of an alternating electric current to become distributed within the current-carrying material such that the current density is largest near the surface and decreases exponentially with greater depth. Thus, the electric current flows mainly at the ‘skin’ of the current-carrying material, in the present case being the semiconductor material.

Thus, with a suitable semiconductor material, the spin aligned electric current through the semiconductor material will be forced to move in two space dimensions on the semiconductor material. The electric current manifests as a two-dimensional distribution of spin-aligned electron current flow on the semiconductor material, akin to a quantum spin hall effect in the semiconductor material.

The distance between adjacent but oppositely spin-polarised electron clusters in the semiconductor material may be in the order of micrometres. It is preferable that oppositely spin-polarised electron clusters are close enough together so that when emitted, their opposite magnetic poles may attract each other and form the collections of condensed plasmoids. The collections may initially form pairs of oppositely spin-polarised clusters that are attracted to each other which may in turn then join with other pairs to form more complex collections, such as ‘chains’ or ‘rings’.

Thus, it is important for a short-duration electrical potential pulse to be applied to the cathode to cause formation of the spin-polarised electron clusters and subsequent condensed plasmoids.

To achieve this very short pulse, the electric pulse generation unit may therefore include a relaxation oscillator, including a capacitor charged by an ohmic resistor with a power supply, wherein in use the capacitor is discharged periodically to the cathode to provide the electric pulses. The power supply may include a high voltage transformer having primary and secondary coils, rectifiers and buffer condensers.

Of course it will be appreciated that other oscillators known in the art that are capable of providing a short-duration pulse may be utilised.

Preferably, the electrical circuit is capable of supplying a voltage gradient over the cathode of greater than 100 Vcm⁻¹.

Plasma discharges (such as the interelectrode discharge described herein) can be categorised according to their characteristics. These characteristics have been grouped into three main groups, known as “dark”, “glow” and “arc” (or “spark”). In a dark discharge, ionisation of the reactant gas occurs but the current is low (<10 μA) and there is no visible emission, hence the term “dark”. In a glow discharge the current is much higher and plasma emits a faint glow, while in an arc or spark discharge large amounts of radiation are produced and a visible spark between the electrodes is observed.

Although it has been found that condensed plasmoids form in dark discharges known as “Trichel pulses” the current is very low and therefore for many applications is not useful. Condensed plasmoids do not tend to form in glow discharges and therefore an apparatus setup to produce glow discharge between the electrodes will not be useful in generating condensed plasmoids.

The apparatus is therefore preferably provided with an interelectrode gap, electric potential, reactant gas and reactant gas pressure such that the interelectrode discharge produced by applying the electric potential is an arc or spark discharge. The parameters necessary to achieve a spark discharge are known and include the voltage, reactant gas composition, reactant gas pressure and interelectrode gap distance between the electrodes. Various combinations of such parameters will produce a spark discharge.

The chamber is preferably formed in a tube such as a glass tube.

The chamber preferably has a vacuum applied to reduce the internal chamber pressure. The internal chamber pressure during operation is preferably less than 1 bar.

The reactant gas is then supplied to the chamber to reach the desired pressure and gas concentration.

Preferably, the apparatus includes a reactant gas source for supplying reactant gas to the reactor chamber. The reactant gas source is preferably a hydrogen gas source. The reactant gas source may include a heating element and container for containing titanium hydride crystals, the element heated to heat the crystals and so release hydrogen gas. The container may be located within the reactor chamber or be separate and in fluid communication with the reactor chamber.

Alternatively, the reactant gas may be provided via an inlet port on the chamber or the chamber may be ‘pre-loaded’ with the reactant gas prior to being sealed.

The reactant gas is preferably a gas capable of being ionized to produce positive ions.

The reactant gas preferably includes hydrogen, or hydrogen isotopes such as deuterium and tritium. In a further embodiment the gas may be a Penning-type mixture. A Penning-type mixture is a mixture of an inert gas with a small amount of another ‘additive’ gas that has lower ionization voltage than the inert gas. An example of a Penning-type gas is 98-99.5% hydrogen with 0.5-2% argon. Such a penning-type gas has unstable electron orbitals in the additive gas elements which ionize the hydrogen for a prolonged time period and may ionize the hydrogen even after the interelectrode discharge has finished.

In one embodiment the Penning-type gas mixture may include a majority hydrogen with an additive gas selected from the group including: helium, xenon, argon, acetylene, mercury.

The gas may be provided directly into the chamber via a gas-source or may be generated in-situ by heating a titanium hydride element in the chamber to release hydrogen gas.

Preferably, the apparatus is operable at a gas temperature of less than 200 degrees Celsius and more preferably at less than 100 degrees Celsius.

As the interelectrode discharges occur and condensed plasmoids form, electrons with sufficient energy emit from the discharge current to the anode, thereby passing into the electrical circuit on the anode side. This emission manifests as an electrical output of high voltage pulses at the anode.

Preferably the electrical circuit includes output electrical circuitry connected to the anode for the purpose of utilising the electrical output. The output electrical circuitry may include different components depending on the load, application or measuring apparatus.

The output pulses may include high (many kV) voltage spikes of short duration that may not be useful for many applications. Therefore, preferably the output electrical circuitry may include some form of low-pass filter, capacitor smoothing circuit, decoupling capacitor, transient attenuator, voltage clamp or other smoothing circuit for regulating the electrical output to a stable DC or AC output.

Thus, the electrical circuit may include an ‘input circuit’, including the power supply and electric pulse generation unit, and an ‘output circuit’, including the output electrical circuitry.

Preferably, the output circuit has the same or similar impedance as the input circuit.

Preferably, the output circuit has the same or similar impedance as the input circuit combined with the reactor.

In one embodiment, the power supply for the input circuit may be provided by an energy storage, e.g. capacitor(s), battery(s) or other energy storage. In a further embodiment, the output circuit is connected to the energy storage and provides power to the energy storage.

According to a second aspect of the present invention there is provided a method of generating a condensed plasmoid, the method including:
applying an electric potential difference between electrodes, the electrodes including a cathode and an anode, the electrodes at least partially extending into a chamber containing a reactant gas, wherein an interelectrode gap is formed between the cathode and anode, the electric potential difference and interelectrode gap being configured such that a plasma forms traversing the interelectrode gap and an interelectrode discharge occurs through said plasma; characterised in that the cathode includes a semiconductor material from which the interelectrode discharge emits, at least one condensed plasmoid thereby emitted with the interelectrode discharge.

As previously mentioned, a condensed plasmoid is a very dense cluster of spin-polarized electrons that binds with other condensed plasmoids to form ‘collections’ of condensed plasmoids. The condensed plasmoid collection thus produces a very high localized negative electric potential. This electric potential may accelerate the ionized reactant gas nuclei (i.e. protons with positive charge) in the gas in the chamber. If the proton velocity reaches a critical threshold (with an energy of about 0.78 MeV) and the proton comes close enough to an electron of a condensed plasmoid, a proton-electron fusion reaction will occur.

The rest mass of an electron and a proton is less than that of a neutron and thus additional energy must be supplied to form the neutron. This energy is provided by the 0.78 MeV acceleration of the proton and represents the mass deficiency to be supplied for energy to be conserved.

Electron-proton fusion may thus occur, resulting in a neutron and neutrino. This generation of neutrons provides a catalyst for further fusion reactions.

The neutrons produced are considered low-energy or ‘cold’ neutrons, in contrast to ‘hot’ neutrons as formed from conventional fission reactions. Such low-energy neutrons have a relatively larger reaction cross section and so more easily react with other particles.

A neutron is electrically neutral and thus there is no Coulomb barrier to overcome in fusion reactions with protons. Neutron-proton, neutron-deuteron and neutron-triton fusion reactions may thus occur at relatively low temperatures compared with ‘hot’ fusion deuterium-deuterium or deuterium-tritium reactions such as in magnetic tokamak reactors.

A neutron-proton fusion reaction may thus occur between the neutrons emitted by the aforementioned electron-proton fusion step with further protons accelerated toward the condensed plasmoids. The neutron-proton reaction forms a deuteron and excess energy of about 2.224 MeV, i.e. the reaction is p+n->d+˜2.224 MeV. The 2.224 MeV of energy released corresponds to the loss in mass as a deuteron has less mass than the combined mass of the proton and neutron. This is also the binding energy of deuterium, i.e. 2.224 MeV.

In turn, a deuteron-neutron fusion reaction may occur between the emitted deuterons and the neutrons, to thereby form tritium. This reaction is d+n->t+6.258 MeV.

These fusion reactions may occur as long as the condensed plasmoids are present and there is a source of protons in the reactant gas, i.e. the reactant gas is positively ionised.

The ‘fuel’ for the reactor is thereby provided by the positive ions in the reactant gas and the condensed plasmoids behave as catalysts. Over time, as more reactions and transmutations occur, the proton ‘fuel’ will dissipate, and further reactions will no longer be possible. However, the energy density available from nuclear fusion reactions is very high and thus even a relatively small quantity of reactant gas can provide sufficient energy for many applications.

The neutrons generated may be bound near the surface of the condensed plasmoids due to the magnetic attraction between the neutrons and electrons on a condensed plasmoid. The energy released from the fusion reactions is thus released on the ‘surface’ of the condensed plasmoids.

When a fusion reaction occurs between such a ‘bound’ neutron and incoming proton or deuteron, the released energy destroys the corresponding condensed plasmoid in an ‘explosive’ burst.

An electron with a sufficiently high energy state will also escape the bounds of its ‘parent’ condensed plasmoid and travel into the anode. It has been found that condensed plasmoids tend to ‘leak’ such electrons to the anode, even without a fusion reaction occurring, and so will naturally dissipate over time.

However, when the fusion reactions take place, the energy released is passed to the electrons of the condensed plasmoid, greatly increasing the number of high energy electrons that are free to move to the anode.

The energy released by the fusion reactions is thus passed to electrons in the condensed plasmoid. The energised electrons are ‘ejected’ from the condensed plasmoid when the condensed plasmoid is destroyed due to the energy release disrupting the magnetic and electric fields holding the condensed plasmoid together. The now free electrons move to the nearest location of lower potential, being the anode.

This results in a so-called electron ‘cloud’ being ejected from the condensed plasmoids to the anode in a rapid burst. This electron cloud ejection occurs very rapidly, in a pulse in the order of magnitude of femtoseconds. Thus, some of the energy, released by the fusion reactions are transferred to the electrons and manifests in the form of an electric pulse, in contrast to the heat generation that has been the goal of fusion reactors to date. The present invention thus provides a potentially far more efficient fusion system than heat-output fusion reactors, which require heat-to-electricity conversion with attendant energy losses.

The condensed plasmoid catalysed fusion reactions mentioned above is analogous to muon catalysed fusion i.e. with the condensed plasmoid being analogous to the muon. The condensed plasmoid collection forms a highly charged pseudo-particle, analogous to a high-mass muon, which is used to draw particles together sufficiently for fusion to occur.

However, condensed plasmoids have advantages over muons in that they have a much longer lifetime than a muon, a very high negative charge and a higher total energy. Generating condensed plasmoids using the apparatus as aforementioned is also less energy expensive than generating muons. Thus, condensed plasmoids may operate as the catalyst for a much longer time with less input energy requirements for generation than a muon.

Thus, the apparatus as aforementioned may be used as an apparatus for catalyzing fusion reactions, including fusion between positive ions in the reactant gas and electrons in the condensed plasmoids and preferably between subsequent neutrons generated and positive ions in the reactant gas.

According to one aspect of the present invention there is provided a method of catalyzing nuclear fusion reactions, the method including applying an electric potential difference between electrodes, the electrodes including a cathode and an anode,
wherein the electrodes extend at least partially into a chamber containing a reactant gas, an interelectrode gap formed between the cathode and anode, the electric potential difference and interelectrode gap being configured such that a plasma of the reactant gas forms at an interelectrode discharge traversing the interelectrode gap, and
characterised in that the cathode includes a semiconductor material from which the interelectrode discharge emits, at least one condensed plasmoid formed with the interelectrode discharge, the condensed plasmoid having a negative charge and higher mass than a proton, thereby accelerating a proton from the reactant gas toward the electron of the condensed plasmoid.

In a further aspect, the neutron fuses with a further proton accelerated toward the condensed plasmoid, wherein the condensed plasmoids accelerate protons and positive ions in the reactant gas toward the condensed plasmoids, fusion occurring between protons in the reactant gas and electrons of the condensed plasmoids to thereby form neutrons,
the neutrons fusing with further protons to form deuterons, thereby releasing energy, some of which is transmitted to electrons of the condensed plasmoid, the electrons emitting to the anode, thereby providing a higher negative electric potential at the anode.

According to another aspect of the present invention there is provided a method of electrical power generation using an apparatus as aforementioned, the method including applying a pulsed potential difference between the electrodes, to form a pulsed plasma in the interelectrode gap therebetween, condensed plasmoids being formed with the plasma to provide a high mass and high charge pseudo-particle,
wherein the condensed plasmoids accelerate protons and positive ions in the reactant gas toward the condensed plasmoids, fusion occurring between protons in the reactant gas and electrons of the condensed plasmoids to thereby form neutrons,
the neutrons fusing with further protons to form deuterons, thereby releasing energy, some of which is transmitted to electrons of the condensed plasmoid,
the electrons emitting to the anode, thereby providing a higher negative electric potential at the anode.

In one embodiment the apparatus as aforementioned may be used for electrical power generation, the apparatus including:
a reactor tube having the cathode and anode,
the anode being covered by a thin layer of semiconductor with rough surface,
a pulsed power supply for electrical excitation of the cathode and an output for electricity from the anode,
a source of hydrogen isotopes or water vapor in the reactor tube,
a source controller that activates the source of hydrogen isotopes,
wherein the power supply and the source controller are adjusted to create:
a) a pulsed plasma forming surface plasmons and condensed plasmoids in the reactor tube between the cathode and the anode,
b) charge density waves on the surface of the cathode will transmute hydrogen nuclei in the plasma into heavier elements and isotopes,
c) emission of electrons from the cathode to the anode, and
d) electricity at the output from the anode.

In another embodiment the apparatus for electrical power generation includes:
a reactor, with a tube forming a chamber therein, the chamber having electrodes, including a cathode and anode, the cathode and anode being covered by a layer of semiconductor material with an inhomogeneous surface,
a pulsed power supply for applying an electrical potential across an interelectrode gap formed between the electrodes,
a reactant gas and means for introducing the reactant gas into the chamber,
wherein the power supply is configured to apply the electrical potential across the electrodes to create:
a) a pulsed plasma in the interelectrode gap,
b) condensed plasmoids in the interelectrode gap,
c) charge density waves on the surface of the cathode,
d) emission of electrons from the cathode to the anode, and
e) a higher negative electric potential at the anode.

As aforementioned, condensed plasmoids can be used to study various effects, including nuclear fusion of various particles. Other plasma and discharge effects may also be manipulated and studied through the use of condensed plasmoids. Moreover, the apparatus may be utilised in spintronic applications as it is capable of producing spin-polarised electron clusters on the cathode.

In condensed plasmoid formation the supply of protons is relatively easily achieved by providing a suitable gas. However, efficient condensed plasmoid generation has proven elusive. In the prior art, although condensed plasmoids may have been produced, the generation efficiency was low and side-effects such as cathode degradation resulted in unviable apparatus. In contrast, the apparatus and methods as aforementioned have been found to reliably produce condensed plasmoids.

Therefore, it can be seen that the present invention offers significant advantages over the prior art including better apparatus and methods for generating condensed plasmoids.

Reference herein is made to various aspects and embodiments of the present invention. For clarity and to aid prolixity every possible combination, iteration or permutation of features, aspects and embodiments are not described explicitly. Thus, it should be appreciated that the disclosure herein includes any combination, iteration, multiple or permutation unless explicitly and specifically excluded.

The order in which aspects, embodiments, features or descriptions occur in this description should not be interpreted to necessarily require the preceding aspects, embodiments, features or descriptions.

### BRIEF DESCRIPTION OF DRAWINGS

Further aspects and advantages of the present invention will become apparent from the following description which is given by way of example only and with reference to the accompanying drawings in which:

FIG. 1 shows a prior art apparatus for generating condensed plasmoids;

FIG. 2a shows a conceptual representation in the prior art of a condensed plasmoid;

FIG. 2b shows a collection of the condensed plasmoids of FIG. 2a;

FIG. 3 shows a prior art x-ray film of a ring-like collection of condensed plasmoids;

FIGS. 4a-4c show a prior art photo sequence of a condensed plasmoid traversing an interelectrode gap;

FIG. 5 shows prior art photographs of condensed plasmoids;

FIG. 6a shows a conceptual representation of a collection of condensed plasmoids;

FIG. 6b shows another conceptual representation of a collection of condensed plasmoids;

FIG. 6c shows a conceptual representation of fusion reactions catalyzed by condensed plasmoids;

FIG. 7 shows conceptual 3D representations of collections of condensed plasmoids;

FIG. 8 shows an apparatus for generating condensed plasmoids according to a first embodiment;

FIG. 9 shows a reactor for the apparatus of FIG. 8;

FIG. 10a shows a lateral cross-section through the reactor at A-A on FIG. 8;

FIG. 11a shows a longitudinal cross-section through the reactor at B-B on FIG. 8;

FIG. 11b shows a longitudinal cross-section through the second embodiment of the reactor;

FIG. 11c shows a longitudinal cross-section through a third embodiment of the reactor;

FIG. 11d shows a longitudinal cross-section through a fourth embodiment of the reactor;

FIG. 11e shows lateral and longitudinal cross-sections through a fifth embodiment of the reactor;

FIG. 11f shows a side view and longitudinal cross-sections of a sixth embodiment of the reactor;

FIG. 11g shows a side view and longitudinal cross-sections of a seventh embodiment of the reactor;

FIG. 11h shows lateral and longitudinal cross-sections through an eighth embodiment of the reactor;

FIG. 11i shows lateral and longitudinal cross-sections through a ninth embodiment of the reactor;

FIG. 12 shows a schematic circuit diagram of an electrical circuit according to one embodiment;

FIG. 13 shows a simplified conceptual diagram of electrodes with spin-polarised charge clusters;

FIG. 14 shows an enlarged simplified conceptual longitudinal cross section of opposing electrode terminal edges;

FIG. 15 shows an oscilloscope plot of input voltage applied to the cathode;

FIG. 16 shows an oscilloscope plot of a single output voltage pulse at the anode;

FIG. 17 shows Paschen curves for various gases;

FIG. 18 shows thermal calibration test results;

FIG. 19 shows power output test results for one preferred embodiment;

FIG. 20 shows a voltage curve of a capacitor in the oscillating input circuit of FIG. 12;

FIG. 21 shows another oscilloscope voltage trace for the input voltage at the cathode, for comparison with the voltage output at the anode as shown in FIG. 22;

FIG. 22 shows an oscilloscope voltage trace for the output voltage at the anode, for comparison with the voltage input at the cathode as shown in FIG. 21;

### BEST MODES FOR CARRYING OUT THE INVENTION

Although specific advantages have been enumerated above, various embodiments may include some, none, or all of the enumerated advantages.

Other technical advantages may become readily apparent to one of ordinary skill in the art after review of the following figures and description.

It should be understood at the outset that, although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described below.

Unless otherwise specifically noted, articles depicted in the drawings are not necessarily drawn to scale. The diagrams will show features and components enlarged or distorted for the purposes of illustration and conveying the principles of the invention. Therefore, it should be appreciated that the scale, dimensions and ratios of features shown in the drawings should not necessarily be seen to be limiting and are primarily for illustrative purposes.

Modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order.

As used in this document, “each” refers to each member of a set or each member of a subset of a set.

TABLE of
drawing references.

| | |
|---|---|
| 1 | apparatus |
| 2 | container |
| 3 | cylindrical compartment |
| 4 | reactor |
| 5 | input wire |
| 6 | input circuit |
| 7 | brackets and spacers |
| 8 | output circuit |
| 9 | capacitor bank |
| 10 | power outlet |
| 11 | power inlet |
| 12 | power supply |
| 13 | electrical circuit |
| 14 | output wire |
| 15 | chamber |
| 16 | Vacuum/gas port |
| 17 | cathode |
| 18 | anode |
| 19 | interelectrode gap |
| 20 | testing electrical circuit |
| 21 | interelectrode discharge |
| 22 | cathode semiconductor material |
| 23 | cathode substrate core |
| 24 | anode semiconductor material |
| 25 | anode substrate core |
| 26 | housing |
| 27 | cathode terminal periphery |
| 28 | anode terminal periphery |
| 29 | cathode alignment terminal |
| 30 | anode alignment terminal |
| 31 | inlet wire sheath |
| 32 | Inlet wire core |
| 33 | Outlet wire sheath |
| 34 | Outlet wire core |
| 35 | Chamber end seals |
| 36 | electrical load circuit |
| 37 | neon tube light |
| 38 | load capacitor |
| 39 | light switch |
| 40 | Electric pulse generation unit |
| 41 | Oscillator capacitor |
| 42 | Oscillator resistor |
| 43a | Input calorimetry flask |
| 43b | Output calorimetry flask |
| 44a | Input thermometer |
| 44b | Output thermometer |
| 45 | resistor |
| 46 | inductor |
| 47 | diode |
| 48 | Pressure gauge |
| 49 | Gas inlet needle valve |
| 50 | Input voltmeter |
| 51 | Output voltmeter |
| 52 | Interelectrode gap traverse axis |
| 53 | Overlapping portion |
| 54 | Insulating stop |
| 55 | Batteries |
| 56 | Transformer |
| 57 | Electron |
| 58 | Proton |
| 59 | Neutron |
| 60 | Deuteron |
| 61 | Triton |
| 62 | Condensed plasmoids |
| 63 | Spin-polarised charge clusters |
| 64 | Skin effect direction |
| 65 | Collection of clusters/condensed plasmoids |
| 66 | Cathode plates |
| 67 | Conductive mounting tube |
| 68 | Insulating layer |
| 69 | Mounting insulation |
| 70 | Cathode Ring mounting |
| 71 | Cathode Ribbon supports |
| 72 | Springs |
| 73 | Spring mounting |
| 74 | Current direction |

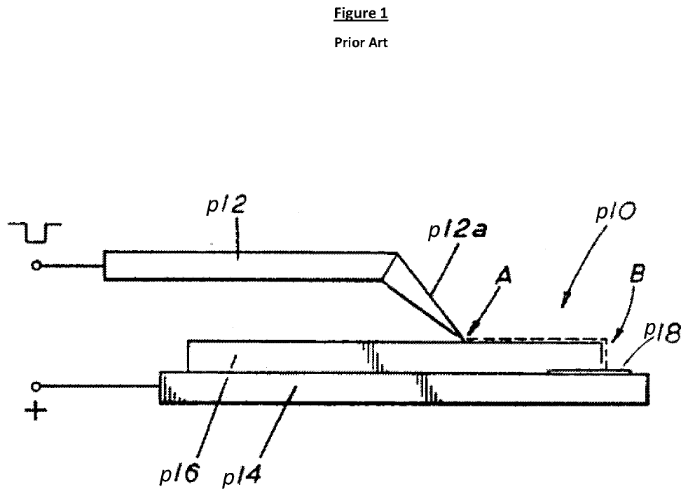

FIG. 1 shows a prior art embodiment (U.S. Pat. No. 5,148,461 by Shoulders) of an apparatus p10 for generating condensed plasmoids. The prior art apparatus generates a condensed plasmoid at the end of a cathode p12 by applying a sufficiently large negative voltage. The cathode p12 has an elongate rod having a neck portion p12a ending in a point and directed generally downwardly toward an anode plate p14 separated from the cathode by an intervening dielectric plate p16. The collector electrode, p14 is maintained at a comparatively positive voltage value, which may be ground, and a negative pulse of the order of 10 kV is applied to the cathode p12 to generate an intense electric field at the cathode p12 point. The resulting electron field emission at the cathode tip forms one or more condensed plasmoids (not shown in FIG. 1) generally in the vicinity where the cathode p12 point approaches or contacts the dielectric at A. The condensed plasmoids are attracted to the anode p14, and travel across the dielectric p16 surface toward the anode p14 along a path generally indicated by the dashed line B. The insulating dielectric plate p16, is preferably of a high-quality dielectric, such as quartz. The plate p16 thus prevents a direct discharge between the cathode p12 and the anode p14 and also serves to provide a surface for the condensed plasmoids travel.

A ‘witness’ plate p18 may be positioned adjacent the anode p14 to intercept the condensed plasmoids from the cathode p12. The witness plate p18 may be in the form of a conducting foil which will sustain visible damage upon impact by a condensed plasmoid. Thus, the witness plate p18 may be utilized to detect the generation of condensed plasmoids as well as to locate their points of impact at the anode p14. Additionally, a condensed plasmoid propagating across the dielectric surface will make an optically visible streak on the surface.

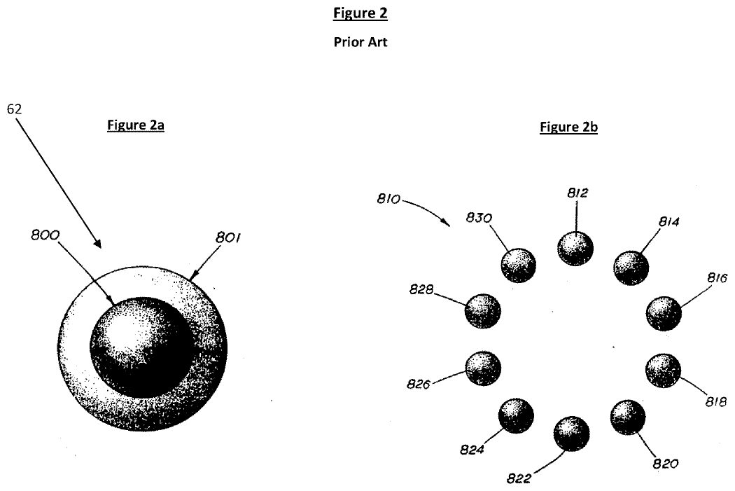

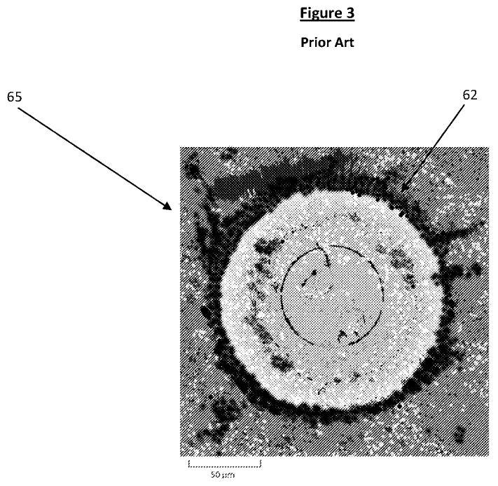

FIG. 2a is a copy of FIG. 60 of U.S. Pat. No. 5,148,461 by Shoulders and shows a conceptualised illustration of a condensed plasmoid 62. The condensed plasmoid 62 has a dense charge cluster 800 of contained electrons which produce a very strong electromagnetic field 801 about the plasmoid.

While individual condensed plasmoids 62 may form a quasi-stable structure, they are rarely observed in an isolated state. Condensed plasmoids 62 exhibit a tendency to link up in a collection, akin to beads in a chain. An example is schematically illustrated in FIG. 2b (FIG. 61 of Shoulders), where the condensed plasmoids 62 in the chain may be somewhat free to rotate or twist relative to each other under the influence of external or internal forces. The chains may be observed to form closed, ring-like, structures as large as 20 micrometres in diameter. Multiple chains may unite and mutually align in relatively orderly fashion. In the chain 810 of FIG. 2b, the ten plasmoids 812, 814, 816, 818, 820, 822, 824, 826, 828 and 830 are shown generally in a circular pattern. Typically, spacing of condensed plasmoids in a chain is approximately equal to the diameter of the individual plasmoids 62. Spacing between chain rings is of the order of one ring diameter. A typical one micrometre wide chain comprised of about ten condensed plasmoids 62 may include 10¹² electron charges. Individual condensed plasmoids 62 may be observed within a chain ring. A condensed plasmoid 62 has the nature of a non-neutral electron plasma and is most strongly bound, with the binding force between condensed plasmoids 62 in a chain being weaker, and the binding between chains of plasmoids 62 being the weakest. However, all of the binding energies appear to be greater than the chemical binding energy of materials.

The prior art refers to the observation of condensed plasmoids 62 in various apparatus and experiments, as shown in FIGS. 3-5.

FIG. 3 shows a large, ring-shaped chain of condensed plasmoids 62 as observed on X-ray film (Matsumoto, 1993). The outer ring of condensed plasmoids 62 usually appears darker on the X-ray film than the bound area which produces a lighter ring on the X-ray film.

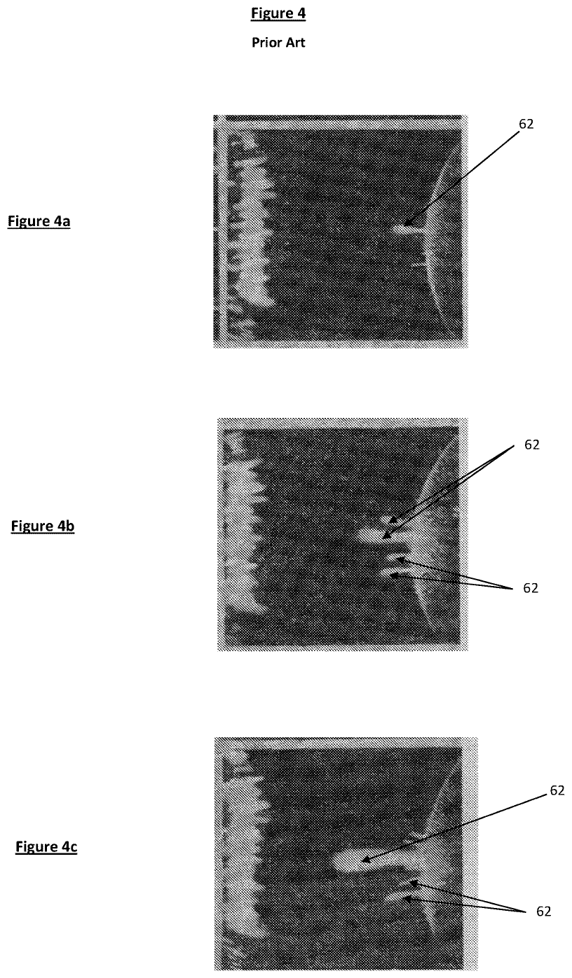

FIGS. 4a-4c are taken from the (Mesyats, 2000) experiments and show a time-sequence of photographs with 50 microsecond intervals. Condensed plasmoids are shown being ejected from an electrode. These condensed plasmoids were produced on a blunt surface, in nitrogen, at atmospheric pressure with an interelectrode distance of 6 cm and an electric field of 5 kVcm⁻¹.

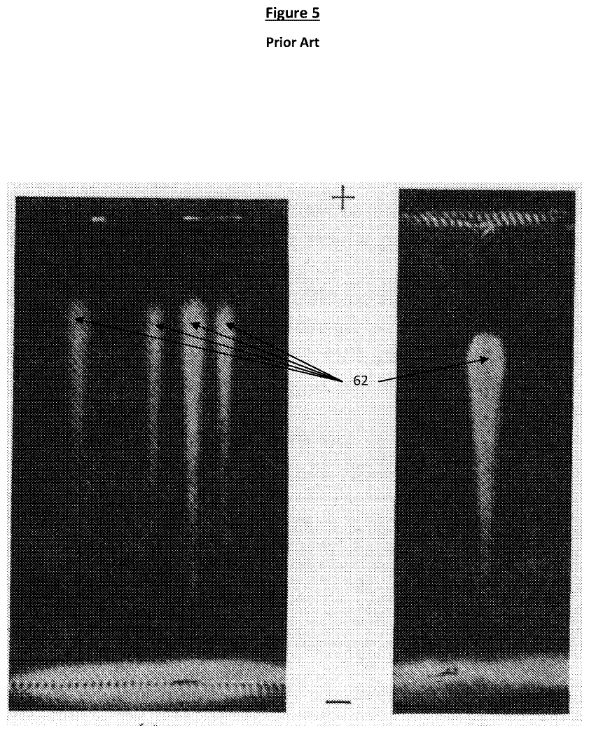

FIG. 5 shows photographs of condensed plasmoids as taken by (Raether, 1988) in his experiments.

Various prior art apparatus and experiments were able to produce such condensed plasmoids to varying degree and effect. However, none have proved effective in reliably reproducing the phenomena, while overheating, electrode deterioration or unstable discharges were common.

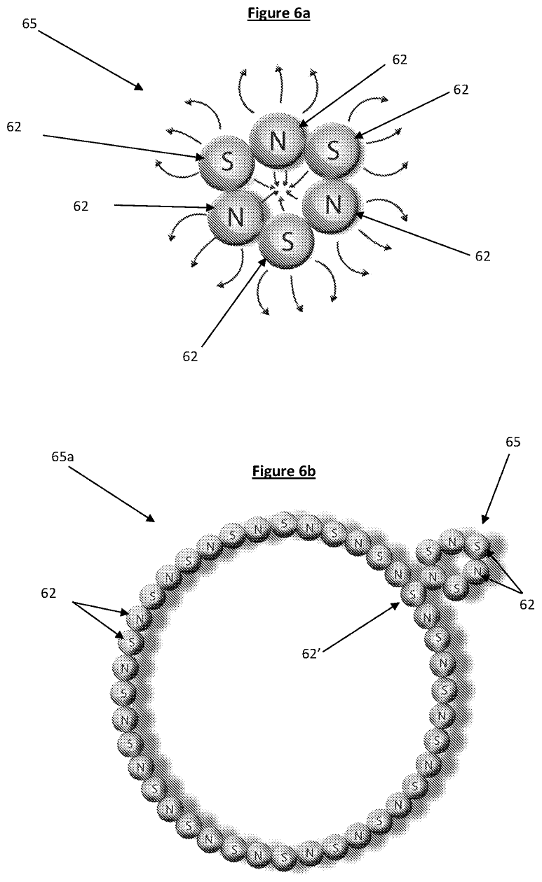

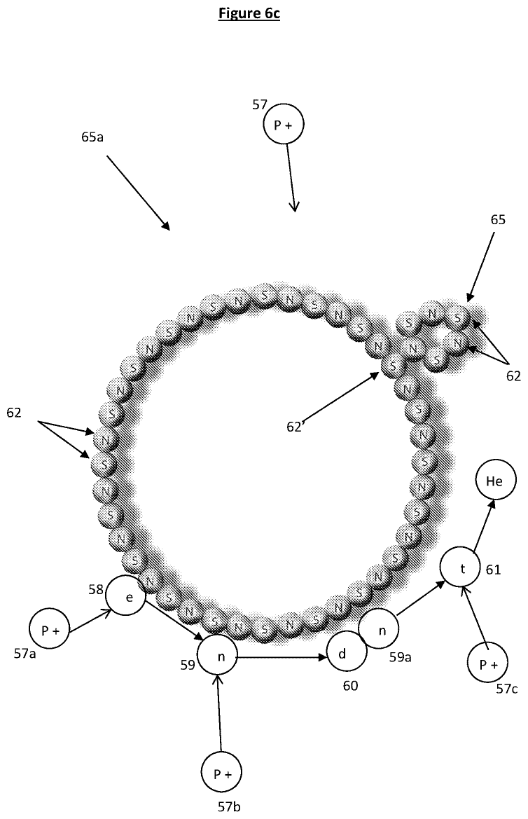

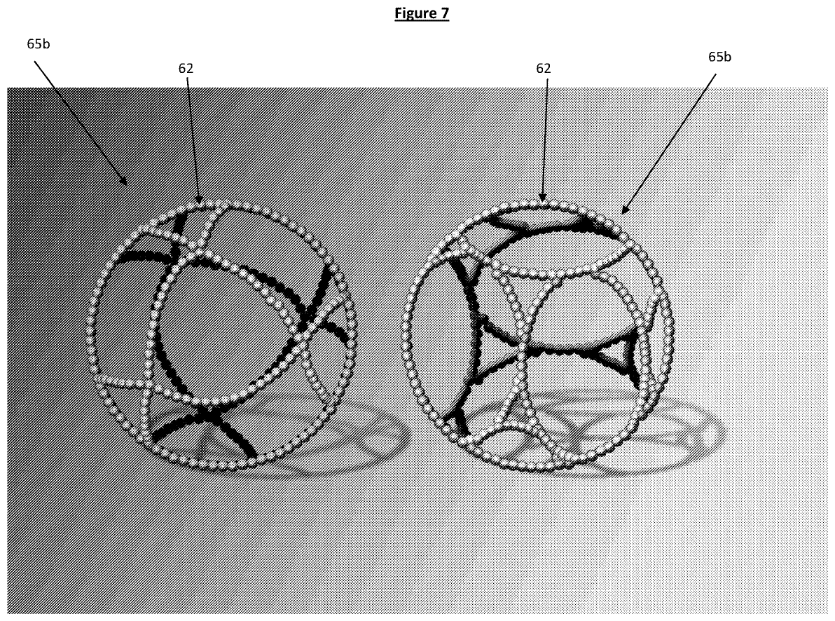

FIG. 6a shows a conceptual representation of a collection 65a of condensed plasmoids 62, which are located in a plasma (not shown). The condensed plasmoids 62 collectively form a ring-like structure of individual plasmoids 62. Each plasmoid 62 is formed from a group of electrons having a majority in one spin-state, thus being a ‘spin-polarised’ cluster of electrons. A cluster is considered ‘spin-polarised’ if the net spin is non-zero.

Each condensed plasmoid 62 has a spin-field dipole. Thus, a corresponding a magnetic dipole is present for each condensed plasmoid 62. The opposite magnetic poles (indicated by N=north, S=south) of adjacent condensed plasmoids 62 are thereby able magnetically attract each other thus forming the chain. Additionally, the existence of an electrostatic repulsion also acts to force the condensed plasmoids 62 apart. If these opposing magnetic and electrostatic fields are balanced, a stable structure is produced. The structure remains stable unless disrupted by a sufficiently strong external electric or magnetic field. The structure will also be disrupted by contact with a grounded or conductive object.

FIG. 6b shows another conceptual representation of a larger collection of condensed plasmoids 62 forming a ring 65a, with a smaller ring collection 65 coupled to a condensed plasmoid 62′ on the larger ring 65a periphery.

Similarly, FIG. 7 shows a conceptual three-dimensional representations of condensed plasmoid collections 65, showing potential collection structure shapes.

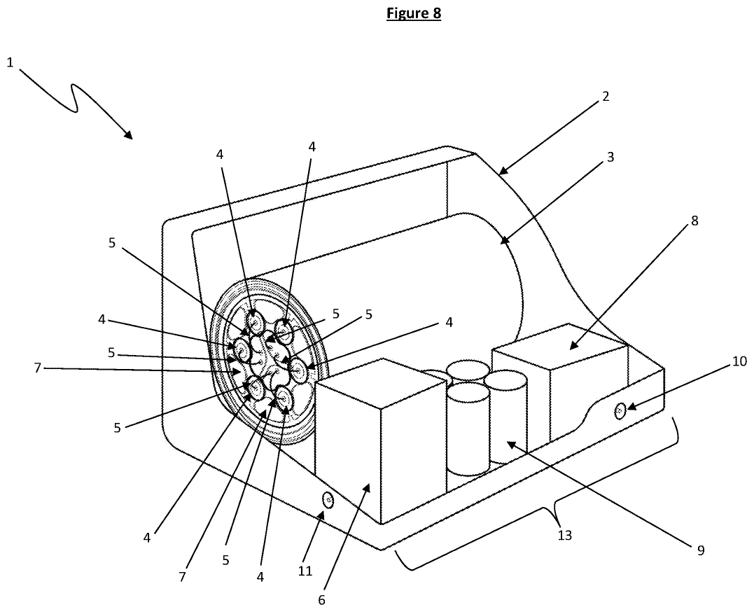

FIG. 8 shows a first preferred embodiment of the present invention in the form of an apparatus 1 for generating interelectrode discharges, including condensed plasmoids. FIG. 8 shows a partially cut-away view of a container 2, to show the internal components. The container 2 encloses the internal components and is shielded with an aluminium or steel lining and interior plastic lining.

The apparatus 1 includes a cylindrical compartment 3. Within the compartment 3, there are six reactors 4, electrically connected by wires 5 to an input circuit 6. Only one end of each reactor 4 is visible in FIG. 8. The compartment 3 includes brackets and spacers 7 for securing the reactors 4 in position and electrically insulating them.

An output circuit 8 manages the output of the reactors 4. The output of the reactors 4 is stored in a capacitor bank 9 and managed by the output circuit 8. The capacitor bank 9 may also act as a smoothing circuit for smoothing the voltage output of the reactors 4.

A power outlet 10 is connected to the output circuit 8. A power inlet 11 is provided for a power supply 12 (shown in FIG. 12) to be connected to. The input circuit 6 manages the input power from the power supply 12.

An electrical circuit 13 is formed by the reactors 4, input circuit 6, output circuit 8 and capacitor bank 9. The capacitor bank 9 may be replaced, or supplemented by, a battery or other electrical charge storage means.

In some embodiments, the power supply 12 may be included as an integral part of the input circuit 6.

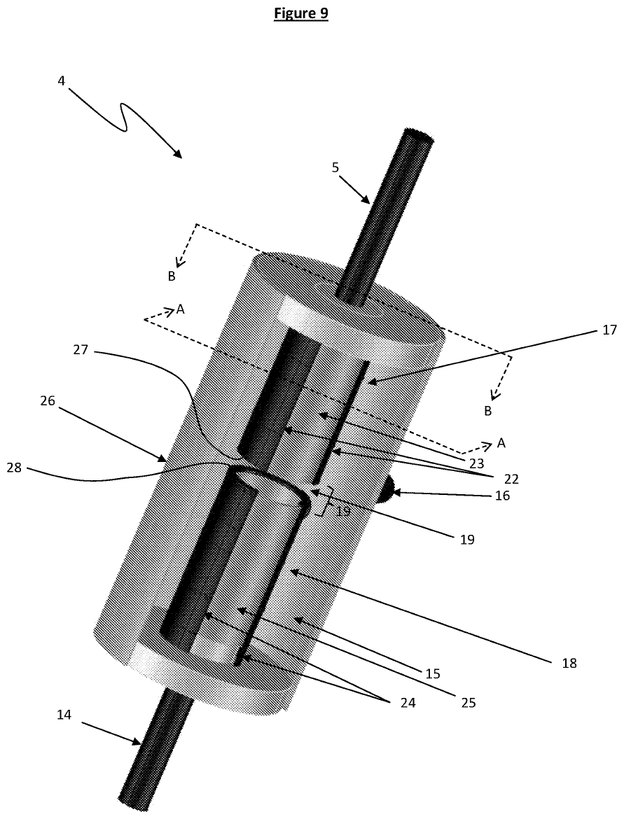

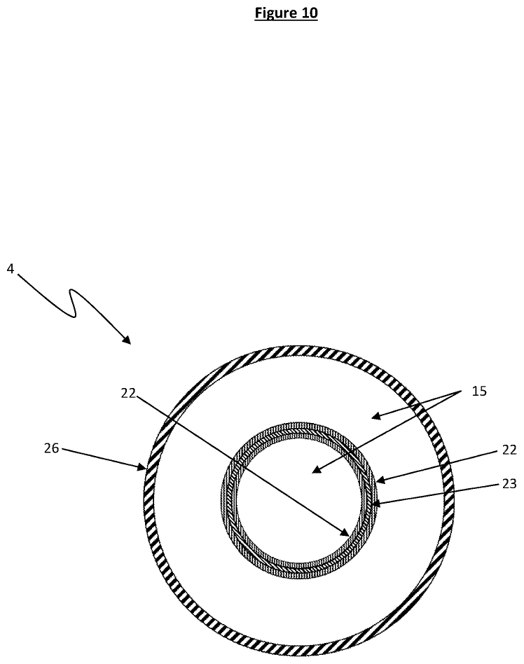

An exemplary reactor 4 is shown in FIG. 9. The reactor 4 includes a wire 5 or other electrical terminal connector connected to the input circuit 6. Another wire 14 (or other electrical terminal connector) connects the reactor to the output circuit 8.

The reactor 4 includes a housing 26 constructed of an insulating material such as glass, quartz or glazed ceramic. The housing 26 is typically a glass tube.

The housing 26 defines the bounds of a vacuum chamber 15 for containing a reactant gas including hydrogen, hydrogen isotopes, or ideally a Penning-type mixture. The reactant gas may be injected via port 16. The port 16 is connected (not shown) at a T-junction to a reactant gas source (not shown) and to a vacuum pump (not shown). A pair of electrodes 17, 18 extend into the chamber 15 and include a cathode 17 and an anode 18.

A vacuum pump (not shown) evacuates the chamber 15 to remove air, moisture or other impurities. The reactant gas is then injected into the chamber 15 to provide a concentrated gas in the chamber. Inserting more gas increases the pressure within the chamber 15.

An interelectrode gap 19 is formed between the electrodes 17, 18.

The cathode 17 is connected to the input circuit 6 via wire 5. The anode 18 is connected to the output circuit 8 via wire 14.

The input circuit 6 and output circuit 8 are also electrically connected to complete the overall electrical circuit 13 combining the input circuit 6, reactor 4, output circuit 8 and capacitor bank 9.

In use, the input circuit 6 applies a rapidly pulsed electric potential difference between the electrodes 17, 18 to cause an interelectrode discharge across the interelectrode gap 19. The discharge ionizes the gas and creates a plasma.

The cathode 17 has an electron discharge material capable of generating spin-polarised electron clusters from an electric current passed through the material. In preferred embodiments this material is provided as a semiconductor surface 22 formed from a semiconductor material. The semiconductor surface 22 is a surface treatment of a conductive metallic substrate 23, e.g. the semiconductor surface 22 may be formed by anodizing an aluminium substrate to make an chalcogenide (aluminium oxide) semiconductor surface 22 coating the conductive substrate 23.

This anodization produces an inhomogeneous semiconductor surface 22 with many small micro-cavities or ‘pores’ that form pathways for electron clusters to emit.

In alternative embodiments, the semiconductor surface 22 may be formed from an applied surface coating or layer.

Similarly, to the cathode 17, the anode 18 also has a semiconductor surface 23 formed on a conductive substrate 25.

The substrates 23, 25 are primarily provided for rigidity and strength and to maintain alignment and shape. The substrates 23, 25 are also electrically conductive and carry electrical current when an electric potential is applied between the electrodes 17, 18.

FIG. 9 is a partial cutaway view and so the semiconductor materials 22, 24 are shown partially cut-away to reveal the underlying substrates 23, 25. Inner semiconductor surfaces coating the inner radial surface of the conductive substrates 23, 25 are not shown in FIG. 9 but are present in preferred embodiments.

The electrodes 17, 18 are both formed from extruded aluminium tubes. The aluminium tubes 17, 18 are immersed in an oxidizer such as chlorine to produce an aluminium oxide semiconductor material coating that forms the semiconductor surface 22. The coating 22, 24 covers the entirety of the substrate 23, 25 in the chamber 15 so that the conductive substrate is exposed to the reactant gas. The aluminium oxide forms the semiconductor material 22, 24 on the electrodes 17, 18 respectively. However, it should be noted that while the electrodes are covered by the semiconductor material 22, 24 at a macro scale, at a micro or nano scale, the anodization process produces an inhomogeneous semiconductor surface 22 with many discontinuities, variations in thickness and cavities or ‘pores’ that form pathways for electron clusters to emit.

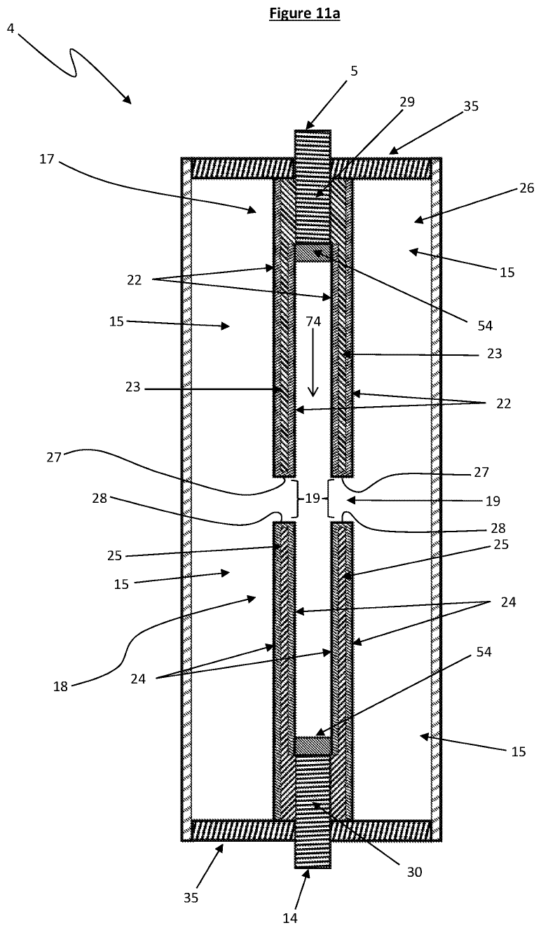

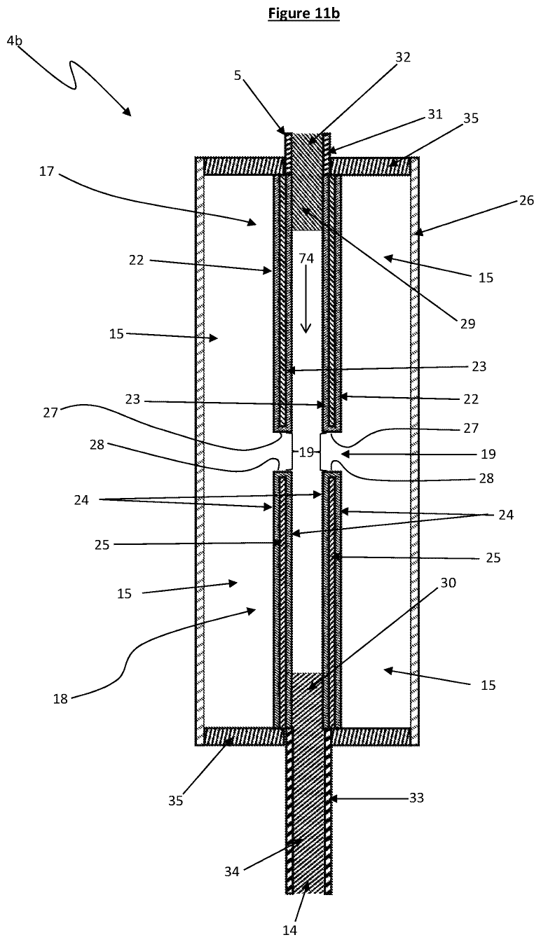

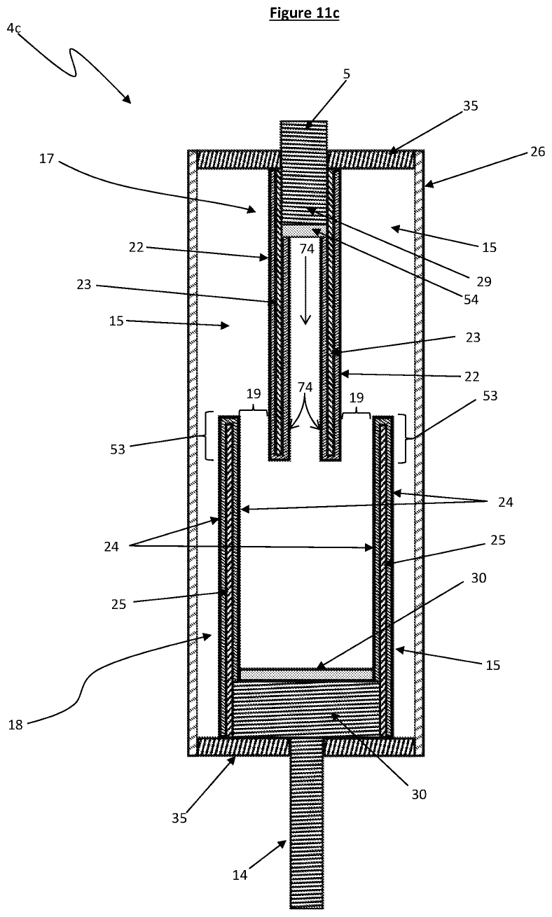

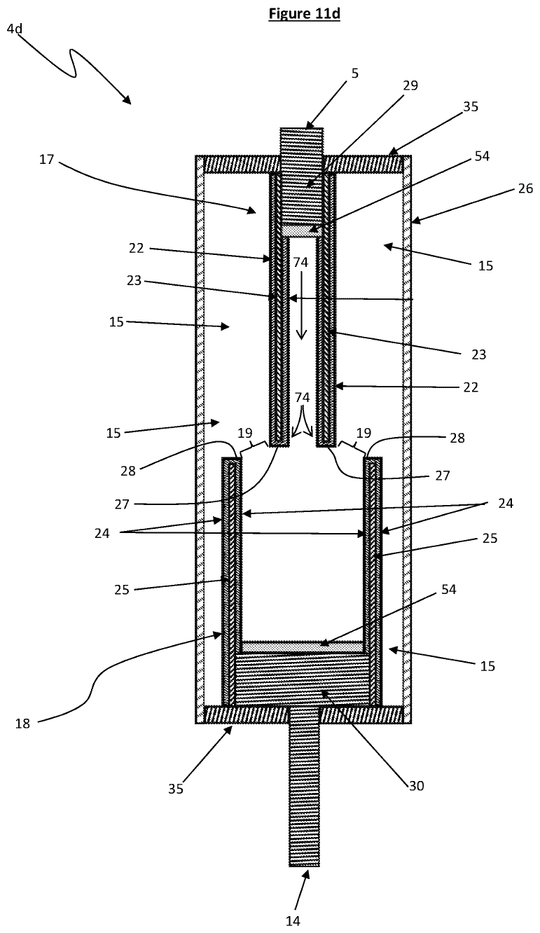

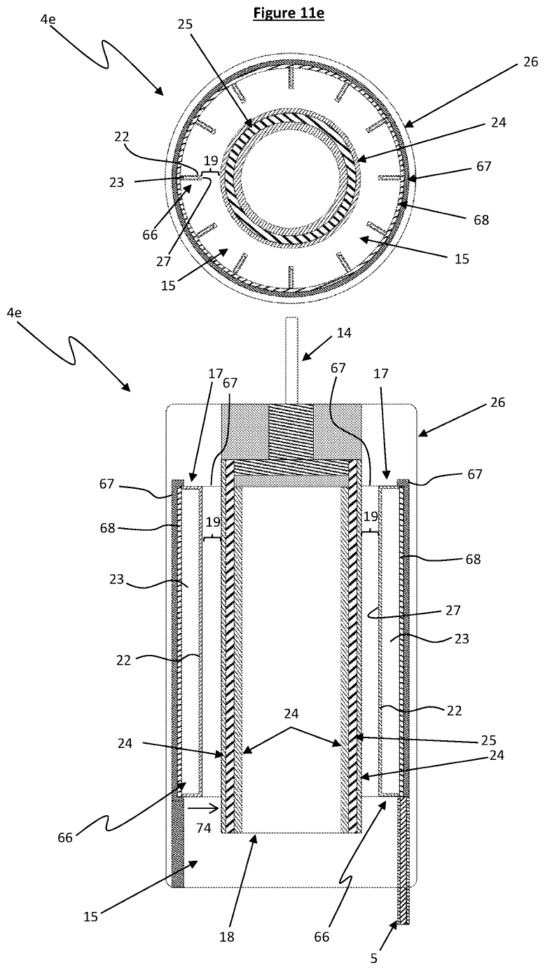

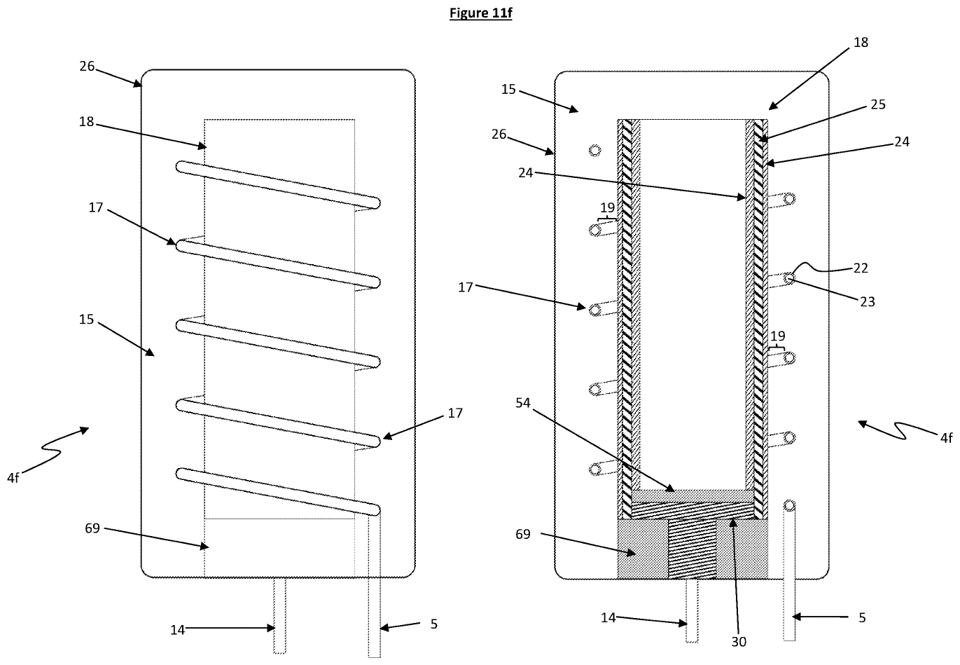

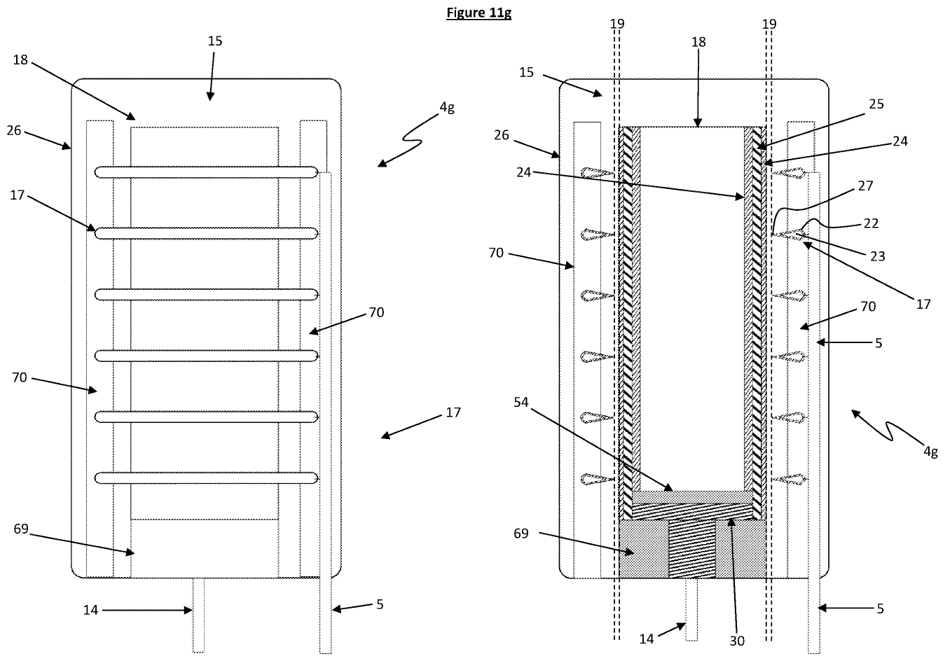

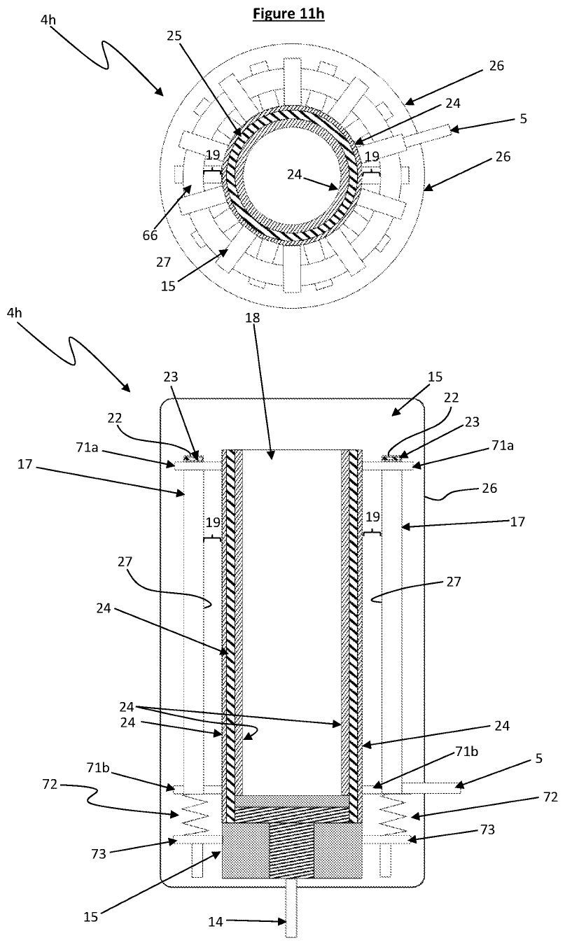

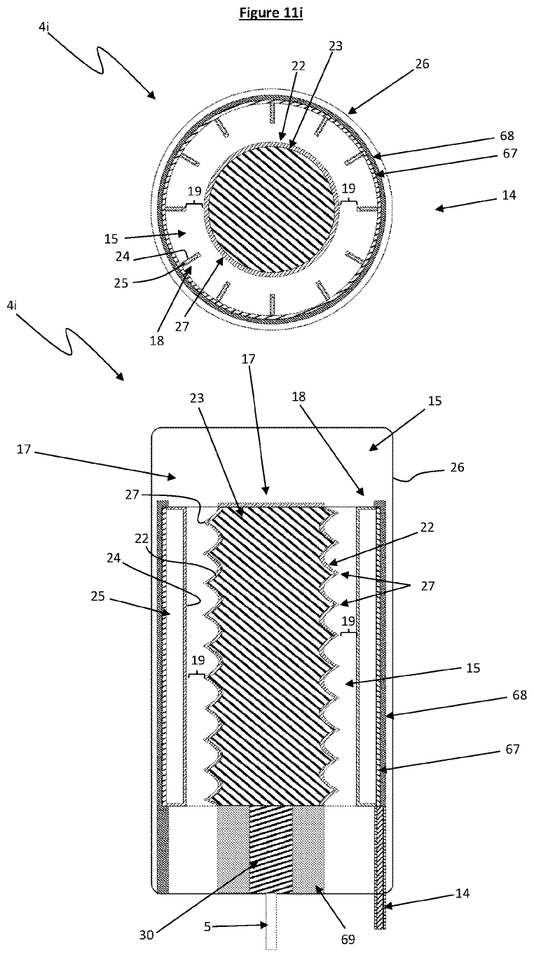

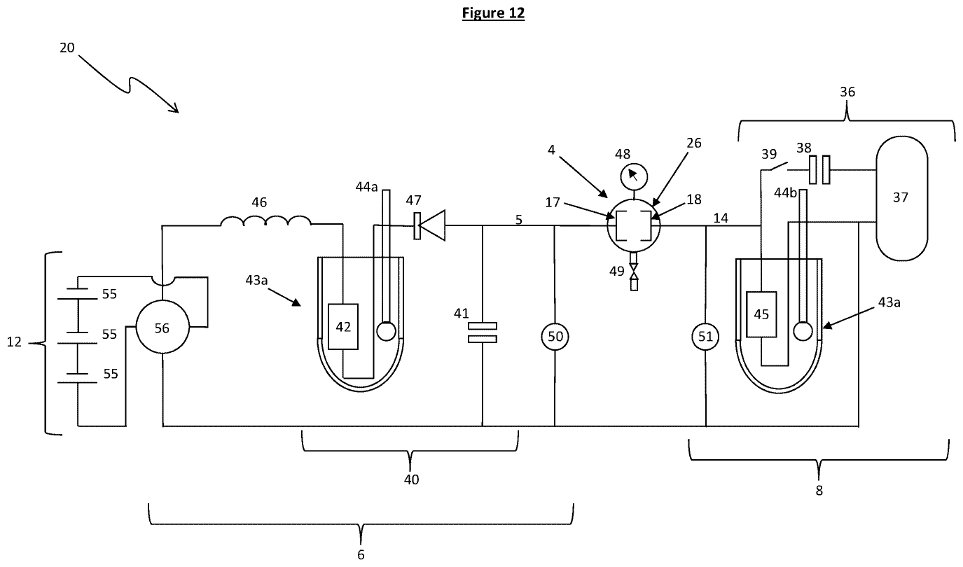

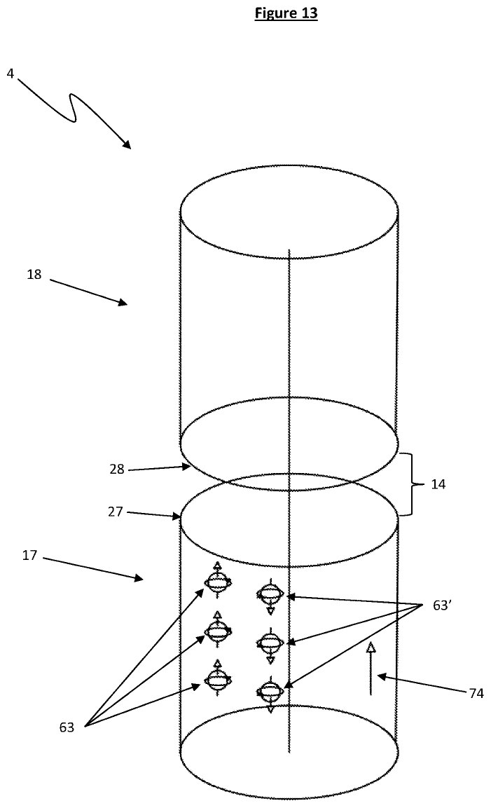

In the embodiments shown in FIGS. 11a-11i the semiconductor surfaces 22, 24 have a thickness between 1 μm and 100 μm. The substrates 23, 25 in FIGS. 11a-11h are between 0.5-2 mm in thickness.

The cathode 17 is formed as a hollow cylindrical electrode with a circular cross-section. Similarly, the anode 18 is formed as a hollow cylindrical electrode of the same diameter. Each electrode 17, 18 has respective terminal peripheries with cuspate ‘edges’ 27, 28 proximal the interelectrode gap 19. The terminal peripheries 27, 28 have a constant mutual separation about their extents. Thus, the interelectrode gap 19 has a constant distance between the extents of the terminal peripheries 27, 28.

It will be appreciated that the electrodes 17, 18, need not have the same longitudinal length, and the cathode 17 for example may be shortened or lengthened to change the characteristics of condensed plasmoid generation. Naturally, the anode 18 would need to have its length or position altered to maintain the interelectrode gap 19 distance with the cathode 17.

Similarly, the positions of the cathode 17 and anode 18 may be swapped.

The housing 26 is made of quartz glass but could be a glazed ceramic or other insulating and/or inert material.

Experiments have shown that irregularities in the inter-electrode gap of as little as 0.1 mm are sufficient to cause the discharges to ‘anchor’ at the shortest interelectrode distance point between the terminal peripheries 27, 28. This ‘anchoring’ causes overheating of the cathode 17 at that point and results in deterioration. This deterioration was a common problem with the prior art apparatus which used sharp, pointed cathodes to concentrate the electric field at a small area and thus reduce the voltage required to cause a discharge. In contrast, the electrode construction shown in FIGS. 9-11 can achieve the necessary electric potential to initiate a discharge while preventing repeated discharges occurring at one point on the circumference of the cathode 17.

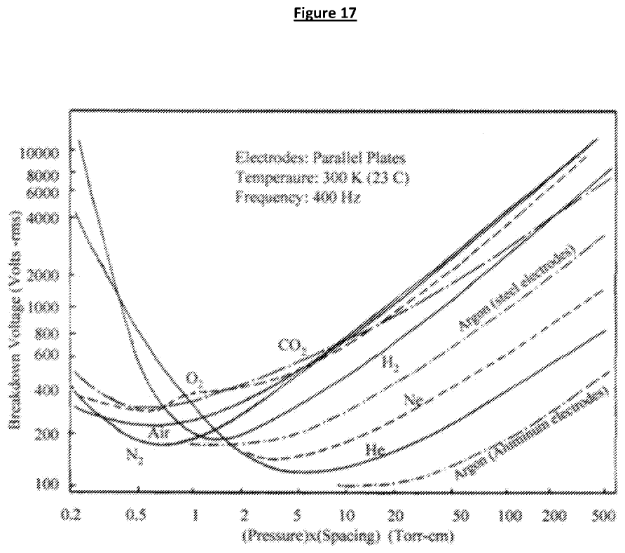

The location that each interelectrode discharge is defined by Paschen's Law which gives the breakdown voltage necessary to start a discharge between two electrodes in a gas. Paschen's Law defines the breakdown voltage as a function of gas pressure and interelectrode gap distance. FIG. 17 shows established Paschen curves for various gases between parallel plate electrodes.

The breakdown voltage is described by the equation:

$${V}_{B} = \frac{Bpd}{ln ( Apd ) - ln [ ln ( 1 + \frac{1}{{γ}_{se}} ]}$$

Where V_{B} is the breakdown voltage in volts, p is the pressure in pascals, d is the gap distance in meters, γₛₑ is the secondary-electron-emission coefficient (the number of secondary electrons produced per incident positive ion), A is the saturation ionization in the gas at a particular electric field/pressure, and B is related to the excitation and ionization energies.

The breakdown voltage required for interelectrode discharges to occur at a particular location on the cathode terminal periphery 27 thus depends on:
a) the shortest distance to the opposing anode terminal periphery 28, and
b) the characteristics (pressure and gas composition) of the reactant gas in the portion of the interelectrode gap 19 over the path defining that shortest distance.

The discharge will occur, reactant gas ionised, and the plasma formed if the electrical potential exceeds the threshold for the given distance and gas characteristics. Immediately following the discharge, the reactant gas in that path will not have as many free ions and the effective electrical potential at that location will be lowered relative to other locations on the cathode terminal edge 27. Thus, subsequent interelectrode discharges occur at different places on the cathode terminal edge 27. This distribution may be random or ordered and depends on the precision of electrode construction and the reactant gas pressure. Hence, controlling the pressure within the chamber is important for efficient operation.

The interelectrode discharge will be ‘anchored’ in a location if imperfections in the terminal peripheries 27, 28 or variations in the interelectrode gap 19 create a shorter portion relative to the rest of the interelectrode gap 19.

Discharge anchoring can also occur if the anode 18 has any exposed conductive substrate portion near the interelectrode gap 19 not covered by semiconductor material 24. This anchoring occurs as the effective potential difference between the exposed conductive substrate portion and the cathode 17 is increased relative to other anode portions that are covered by semiconductor material 24.

Thus, utilising cylindrical electrodes 17, 18, orientated and configured with a constant interelectrode gap 19 about the extents of their terminal peripheries 27, 28 provides an effective method for preventing or at least minimising any anchoring of the interelectrode discharges 61.

The cathode 17 and anode 18 are formed as hollow cylinders formed from conductive substrates 23, 24 electrically connected to connectors 5 and 14 respectively. The electron discharge materials are made from semiconductor materials 22, 24 formed as coatings covering the terminal peripheries 27, 28 and radially inner and outer surfaces of the electrodes, 17, 18. The semiconductor materials 22, 24 are formed from a glassy, amorphous, chalcogenide material such as aluminium oxide.

Chalcogenide materials include Oxygen, Sulphur, Selenium, Tellurium. Alternatively, materials of group V may be included such as vanadium, nitrogen, phosphorous, arsenic, antimony or bismuth.

Other semiconductor materials may be used such as silicon carbide, zinc oxide or lead sulphide. One example is an electrode composed of an alloy of copper 5%, aluminium 10%, lead 55% and sulphur 30%.

A wide range of cathode and semiconductor materials may be used depending on the application and other apparatus parameters, though materials formed with Chalcogenide elements have shown to be optimal for most applications.

FIG. 10 shows a lateral cross-section of the cathode 17 through section A-A marked on FIG. 9. The anode 18 is constructed in the same manner and so has the same cross-section.

Similarly, FIG. 11a shows a longitudinal cross-section of the cathode 17 through section B-B as marked on FIG. 9.

The embodiments of FIGS. 11a-11i generally have the same or similar components and thus common reference numerals are used throughout.

The reactor 4 in FIG. 11a has a cathode semiconductor surface 22 fully covering the cathode substrate 23. The cathode semiconductor surface 22 extends to cover the radially inner surface of the cathode substrate 23. The semiconductor surface 22 thus covers both the radially inner and radially outer surfaces as well as terminal periphery 27.

Similarly, the anode has semiconductor surface 24 that extends to cover the radially inner surface of the anode substrate 25. The semiconductor surface 24 thus covers both the radially inner and radially outer surfaces as well as terminal periphery 28.

The semiconductor surfaces 22, 24 are inhomogeneous, i.e. not having a smooth, consistent structure. The inhomogeneous nature of the surface ensures that there are very small (micro or nano scale) pathways for electrons to pass from the underlying substrate 23.

The cathode 17 and anode 18 have respective electrical connectors 5, 14 that extend into the chamber and form respective alignment terminals 29, 30 for aligning the electrodes 17, 18. The alignment terminals 29,30 also electrically connect the electrode substrates 23, 25 via connectors 5, 14 to the input 6 and output 8 circuits. The terminals 29, 30 act as an alignment mechanism, with the electrodes 17, 18 being sleeved or screwed to their respective terminal 29, 30 when the reactor 4 is assembled.

Insulating silicon chamber end seals 35 are provided at either end of the housing 26 and hermetically seal the chamber 15 as well as provide some structure for aligning the electrodes 17, 18.

Condensed plasmoids 62 are destroyed if they contact a conductive object. Condensed plasmoids 62 also tend to be attracted to any nearby conductive object. Therefore, it is important to prevent or at least minimise any conductive component exposed in the chamber 15 which could destroy the condensed plasmoids 62. Insulating plugs 54 are thus provided over the ends of the conductive alignment terminals 29, 30 occluding the conductive terminals 29, 30 from the chamber 15, which could otherwise destroy condensed plasmoids 62 emitted from the semiconductor surface 22. The plugs 54 may be provided as rubber stops or a layer of non-conductive glue.

FIG. 11b shows an alternative embodiment through a longitudinal section equivalent to B-B shown in FIG. 9.

The embodiment shown in FIG. 11b shows a reactor 4b generally similar to that shown in FIGS. 9, 10 and 11a. The primary difference is that the input and output wires are sheathed. The input wire 5 has an insulating sheath 31 over a copper core 32. The wire 5 is connected to the rigid conductive alignment terminal 29 that is electrically connected to the cathode substrate 23.

The output wire 14, similarly has a sheath 33 over copper core 34.

FIG. 11c shows another embodiment of a reactor 4c but with overlapping coaxial electrodes 17, 18. The cathode 17 has a smaller diameter than the anode 18 and thus the interelectrode gap 19 is formed as an annulus between the cathode (radially outer) semiconductor surface 22 and anode (radially inner) semiconductor surface 24. The interelectrode gap may thus be considered to be defined as an annular area bound by brackets 53 and 19 shown in FIG. 11c.

In the coaxial embodiment of FIG. 11c the interelectrode discharge will occur perpendicular to the cathode semiconductor surface 22 across the interelectrode gap 19 at locations within the overlapping portion indicated by brackets 53.

Another embodiment is shown in FIG. 11d with a reactor 4d which may provide a coaxial electrode arrangement while not including any overlapping portions 53 as in FIG. 11c. The embodiment of FIG. 11d has a majority of the semiconductor surface aligned parallel with the current direction 74. The terminal peripheries 27, 28 provide very sharp opposing portions that thus concentrate charge and reduce the electric potential required for an interelectrode discharge to occur relative to that shown in FIG. 11c.

It will be appreciated that in alternative embodiments the electrode arrangements of FIGS. 11c and 11d may be reversed, i.e., with the cathode 17 being the larger diameter electrode.

FIG. 11e shows another embodiment of a reactor, labelled ‘4e’, with schematic lateral and longitudinal cross-sections.

The reactor 4e functions similarly to the previous embodiments and like parts are referenced similarly. The reactor 4e differs in structure in that the anode 18 is provided as a central cylindrical anode 18 with a cathode 17 formed by a radially arranged series of twelve plates 66 (only one labelled in lateral cross-section for clarity). Twelve plates 66 are used in this schematic diagram but more or less plates 66 may be used depending on the size of the anode 18.

Each plate 66 has a conductive substrate 23 covered by an inhomogeneous semiconductor material 24. The substrates 23 are conductively connected to each other via a conductive mounting tube 67 which also holds the plates 66 in position about the anode 18. The conductive mounting tube 67 is insulated from the chamber 15 by a plastic insulating layer 68. Insulated input wire 5 is electrically connected to the conductive mounting tube 67 and insulated output wire 14 is attached electrically connected to the anode 25.

As per the embodiments of 11a and 11b, the cathode (plates 66) has semiconductor surfaces 22 that are aligned generally coincident, or at least parallel, with the interelectrode gaps 19. The interelectrode gaps 19 between each plate 66 and the anode 18 all have the same separation to prevent discharges ‘anchoring’ on one of the plates 66.

The embodiment of FIG. 11e thus provides another reactor structure in which to generate the condensed plasmoids.

FIG. 11f shows another embodiment of a reactor, labelled ‘4f’, with a schematic side view and longitudinal cross-section therethrough.

The reactor 4f functions similarly to the previous embodiments and like parts are referenced similarly. The reactor 4f differs in structure as the anode 18 is provided as a central cylindrical anode 18 with a cathode 17 formed by a rigid helical wire formed from the cathode conductive substrate 23 coated with an inhomogeneous semiconductor material 22. The interelectrode gap is thereby formed as a helical path between the cathode wire 69 and outer semiconductor surface 24 of the anode 18. The cathode 17 has a fixed separation over its length and therefore the interelectrode gap 19 is also constant over the extents of the cathode 17.

The relative dimensions of the reactor 4f can be altered to suit the application and tune the reactor 4f, e.g. the anode 18 or helical cathode 17 may be made with smaller or larger diameters as needed. The helical cathode 17 may be made with more or less turns as required.

While the embodiment of FIG. 11f may function, it is unlikely to be as efficient at generating condensed plasmoids as the embodiment of 11a because the cathode semiconductor surface 22 is not aligned parallel or coincident with the interelectrode gap 19. Neither is the anode semiconductor surface 24.

An insulated input wire 5 connects to the cathode 17. The output wire 14 is also insulated and is connected to the conductive substrate 25 of the anode 18 via alignment terminal 30. Similarly to the embodiments of FIGS. 11c and 11d, the anode 18 is mounted via an anode alignment terminal 30 with insulating stop 54. As the anode 18 is located centrally in the tube, the portion of the alignment terminal 30 beyond the extents of the anode 18 are insulated with mounting insulation 69 to prevent the conductive alignment terminal 30 being exposed to the chamber.

FIG. 11g shows yet another embodiment of a reactor 4g. The reactor 4g differs from the reactor 4f in that instead of a helical cathode 17, the cathode is formed as a series of six parallel rings.

Each cathode ring 17 has a conductive substrate 23 coated with a semiconductor material 22. The cathode rings 17 are mounted via cylindrical mounting 70 that is constructed form an insulating material, such as a plastic. The relative dimensions of the reactor 4g can be altered to suit the application and tune the reactor 4g, e.g. the anode 18 or cathode rings may be made with smaller or larger diameters as needed. The number of rings 17 may also be varied as needed.

Each cathode ring 17 tapers to a narrow inner diameter that forms the terminal periphery 27 of the cathode 17. The semiconductor surface 22 is thus aligned more closely to parallel to the interelectrode gap 19 than the embodiment 4f of FIG. 11f and is therefore more efficient at generating condensed plasmoids.

FIG. 11h shows another embodiment of a reactor 4h with longitudinal and lateral cross-sections. The reactor 4h utilises a thin metallic ribbon cathode 17 that extends and undulates between supports 71a, 71b as it encircles a cylindrical anode 18. Springs 72 are attached to lower supports 71b and extend to a lower spring mounting 73. The lower supports 71b may move relative to the upper supports 71a and thus the springs 72 may act as a tensioning system to tension the ribbon cathode 17 to maintain alignment and a constant interelectrode gap 19.

The ribbon cathode 17 is formed from aluminium or other conductive substrate 23, with a surface treatment to oxidise the surface and thereby form the semiconductor surface 22. The input wire 5 is conductively connected to a portion of the cathode 17 near one of the lower supports.

The anode 18 is constructed as per the previously described embodiments 4f-4g. The reactor 4h provides a cathode 17 with semiconductor surfaces 22 aligned parallel with the interelectrode gap 19 and due to the nature of the ribbon cathode being thin, maximises the semiconductor surface 22 area relative to the conductive substrate 23. Additionally, the terminal periphery 27 is relatively thin, enabling the electrical potential and spin-polarised charge clusters 63 to concentrate and thereby more efficiently produce condensed plasmoids 62 during the interelectrode discharge.

FIG. 11i shows another embodiment of a reactor 4i with longitudinal and lateral cross-sections. The reactor 4i has the cathode 17 located centrally and surrounded by 12 radially oriented plate anodes 18.

As with the other embodiments 11a-11h, the cathode 17 is formed by a conductive substrate 23 and an exterior semiconductor layer 22. The cathode 17 in the reactor 4i is formed as a column with an exterior surface having a helical ridge, akin to a screw thread. The apex of the helical ridge forms the terminal periphery 27 of the cathode 17. The terminal periphery 27 is thus relatively sharp to concentrate charge thereon and from which the interelectrode discharge emits. The adjacent semiconductor surface 22 is thus aligned more closely to parallel to the interelectrode gap 19 than the embodiment 4f of FIG. 11f and is therefore more efficient at generating condensed plasmoids.

An exemplary experimental testing electrical circuit 20 according to one embodiment is shown in FIG. 12 and includes an input circuit 6, reactor 4, output circuit 8 and power supply 12.

An example load circuit 36 is included as part of the output circuit 8. The load is provided in the form of a neon tube light 37 and load capacitor 38. A switch 39 is provided to connect the load circuit 36 to the reactor 4 and rest of output circuit 8 and thereby close the load circuit 36.

The input circuit 6 includes an electrical pulse generation unit 40 provided in the form of a capacitive relaxation oscillator including a capacitor 41 and high ohmic resistor 42. The capacitor 41 is charged by the power supply 12, causing the voltage across the capacitor to rise. The capacitor voltage reaches its threshold (trigger) voltage and then its conductance rapidly increases, which quickly discharges the capacitor. When the voltage across the capacitor drops below the threshold voltage, the capacitor stops conducting and the charges again.

In combination with the pulse generator 56, the relaxation oscillator 40 can be used to provide controlled, high-frequency voltage pulses to the cathode 17.

An inductor 46 and diode 47 are included to act as a ‘valve’ to prevent back current which can occur when fusion reactions in the reactor 4 produce a ‘kickback’ electric potential on the cathode 17. The valve 46, 47 acts to prevent current through the resistor 42 and therefore additional dissipation of energy has heat from the resistor.

The embodiment shown in FIG. 12 is designed for experimental testing and thus includes a flask of oil 43a, with thermometers 44a to act as a calorimetry unit for measuring heat output of resistor 42. Similarly, the output circuit 8 includes a flask of oil 43b with thermometer 44b to act as a calorimetry unit for measuring heat output of resistor 45. In commercial production these calorimetry units would not be needed.

A pressure gauge 48 is provided for measuring the pressure within the chamber 15 and a vacuum pump (not shown) is connected to evacuate the reactor chamber 15. The hydrogen gas source is connected via a needle valve 49 which connects to port 16 shown in FIG. 9. Control of the internal chamber pressure can thus be achieved by operation of the vacuum pump 48 and needle valve 49. The pressure of the reactant gas in the chamber is ideally above at least 0.2 Bar.

The process for preparing the reactor 4 for operation involves the vacuum pump operating to evacuate the chamber 15, reducing pressure to about 1 Torr (z 1 mbar). The needle valve 49 is then opened to release reactant gas (e.g. Hydrogen) into the chamber 15 until the pressure reaches the desired level, e.g. 0.8 bar. This process is repeated to eliminate air from the chamber 15.

Prior art electrode discharge systems typically tried to achieve discharge at much lower pressures, i.e. less than 0.005 Bar, to require the lowest breakdown voltage possible for a particular gas, see FIG. 17.

One of the problems with operating at low pressures is that a more expensive vacuum pump and seals are required, and at extremely low pressures (<0.001 Bar) gases require an increasingly high breakdown voltage to form a plasma.

The reactor 4 is not constrained to a particularly low voltage requirement and can use a very high voltage (e.g. >25 kV) to initiate the discharge. This enables the use of much higher pressures in the chamber and consequently use of a higher concentration of reactant gas.

Harvesting the output directly is difficult as the output at the anode 18 contains a series of short-duration and high voltage pulses that need to be smoothed in order to be utilised by many electrical loads.

A smoothing circuit (not shown) is thus ideally incorporated in the output. The smoothing circuit may include fast ‘pulse’ capacitors, such as high-voltage polypropylene-film capacitors, that are constructed to have both low equivalent series resistance (ESR) and low equivalent series inductance (ESL). The smoothing circuit may thus smooth out the high-voltage, short-duration output voltage pulse and provide a more useful output power supply.

The output circuit 8 is ideally constructed such that the total impedance of the output circuit matches the total impedance of the input circuit 6. This impedance matching is important for maximum power transfer. An imbalanced circuit will result in signal reflection and power losses. Similarly, the impedance of the reactor 4 should be matched to the input 6 and output 8 circuits.

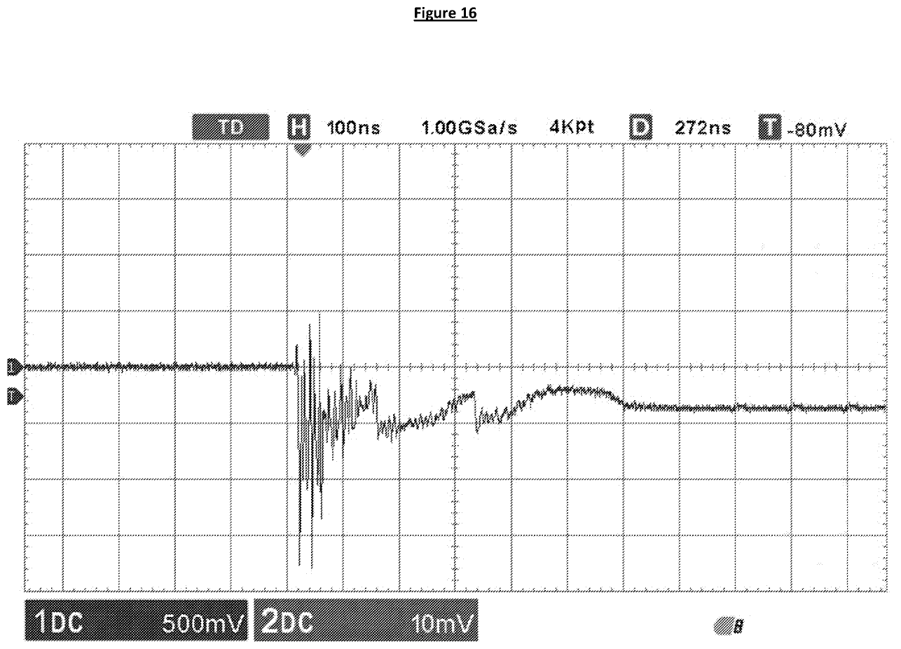

Two voltmeters 50, 51 are provided for measuring the electric potential at the cathode 17 and anode 18 respectively. A measured plot of an exemplary input cathode voltage against time at voltmeter 50 is shown in FIG. 15 and shows six input pulses. The plot has a scale of 10V per voltage division and 2 ms per time division. The input voltage pulses occur as a ‘sawtooth’ pattern with a straight voltage spike followed by a decay.

A measured plot of an exemplary output anode voltage pulse at voltmeter 51 is shown in FIG. 16. The plot has a scale of 50V per voltage division and 100 ns per time division. The time-scale is too short in this plot to see the full dissipation of the output pulse which occurs over about one microsecond.

The power supply 12 is a fast switching, high-frequency power supply including for example batteries 55 connected to a high-voltage, high-frequency switching transformer 56 which steps-up the voltage from batteries 55 to provide the necessary high-voltage input pulses.

The exemplary components of the apparatus have been described above with respect to FIGS. 8-12. The operation and parameters of the apparatus will now be described.

Prior art electrodes used in reactors are constructed from conductive metals as this naturally maximises the current flow through the electrodes with minimal heat loss. However, preferred embodiments of the present invention utilise a cathode 17 and an anode 18, both covered with semiconductor surfaces 22, 24 respectively.

The semiconductor surfaces 22, 24 are specifically included to aid in condensed plasmoid generation. There are a number of reasons why condensed plasmoids form more efficiently from a cathode semiconductor surface 22.

As aforementioned, a condensed plasmoid is formed from a dense cluster of electrons that can travel through the plasma, traversing the interelectrode gap 19. In the prior art, this dense cluster was formed by concentrating the electrons at a very small area on the cathode, e.g. by making a pointed or otherwise ‘sharp’ cathode facing the anode.

In preferred embodiments of the present invention, a different mechanism is used that utilises the particular properties of some semiconductors to form spin-polarised clusters of electrons on the semiconductor surface. It has been observed by the inventor that using a semiconductor material 22 on a cathode 17 where the semiconductor surface 22 is aligned parallel or coincident with the discharge current through the interelectrode gap produces significantly more condensed plasmoids than a metal cathode and much more reliably. A theory as to why a this is the case will now be outlined.

Understanding why the condensed plasmoids form requires an understanding of several concepts, including spin-polarisation, spin hall effect, cold field emission and the skin effect, amongst others. These concepts will now be elaborated individually.

Electrons possess a “spin” angular momentum in addition to a charge. Electron spin is either +½ or −½, i.e. an electron can ‘spin’ either ‘clockwise’ or ‘anticlockwise’ around its own axis with constant frequency. These spin states may also be referred to as spin ‘up’ and spin ‘down’. The two possible spin states naturally represent the “0” and “1” states in logical operations and have thus been used for data storage and computation spintronics applications. Spintronics devices utilise this spin property instead of, or in addition to, the electric charge. The spin states also have different energy states with spin ‘down’ states (−½) having a higher energy state than spin ‘up’ states. Spin state can be altered by adding energy of correct frequency, thereby ‘flipping’ the spin state.

For electron spin to be successfully employed in a ‘spintronic’ device, the control of electron charge and electron spin in a semiconductor is critical to the device functionality. Spintronics devices rely primarily on three different key processes to use the electron spin in a semiconductor. These three processes are known as “spin injection”, “spin manipulation” and “spin detection”. “Spin injection” is the most relevant method for the purposes of the present invention and refers to ‘injecting’ spin-polarised electron clusters into a material such as a semiconductor.

The present invention is able to generate such spin-polarised electron clusters in the semiconductor surface 22 by utilising the Spin Hall Effect (SHE). The Spin Hall Effect is a transport phenomenon determined by Russian physicists Mikhail I. Dyakonov and Vladimir I. Perel in 1971. The SHE consists of the appearance of spin-polarised electrons on the lateral surfaces of an electric current-carrying sample, the spin polarisation (‘spin state’ or ‘spin orientation’) being opposite on the opposing boundaries. In a cylindrical metal wire, the current-induced surface electron spins will orientate themselves to wind around the wire. When the current direction is reversed, the directions of spin polarisation are also reversed.

Similarly, an electrical current in a semiconductor may induce spin polarisation in the semiconductor surface 22. This occurs in a thin layer near the semiconductor surface-gas interface. Thus, by passing a current through the semiconductor coated cathode 17 spin-polarised clusters of electrons form in the semiconductor material 22.

However, while the spin-polarised clusters form, their stability is affected by the magnitude of the ‘spin-relaxation’ time—which defines the time taken for the electron spin to return to its equilibrium state. This spin-relaxation time is affected by multiple variables but is mostly influenced by what is known as ‘spin-orbit coupling’ (SOC).

In quantum physics, the spin-orbit coupling (also called spin-orbit effect or spin-orbit interaction) is a relativistic interaction of a particle's spin with its motion inside a potential. A key example of this phenomenon is the spin-orbit interaction leading to shifts in an electron's atomic energy levels, due to electromagnetic interaction between the electron's magnetic dipole, its orbital motion, and the electrostatic field of the positively charged nucleus.

This phenomenon is detectable as a splitting of spectral lines, which can be considered as a ‘Zeeman effect’ i.e. the effect of splitting of a spectral line into several components in the presence of a static magnetic field. This phenomenon is a product of two relativistic effects: the apparent magnetic field seen from the electron perspective and the magnetic moment of the electron associated with its intrinsic spin.

The mechanisms of decay for a spin polarized cluster can be broadly classified as spin-flip scattering (spin relaxation or spin-lattice relaxation) and spin dephasing (or spin decoherence). The different mechanisms responsible for the spin relaxation time includes:
Elliot-Yafet mechanism, for elemental metals and semiconductors at low temperatures.
D'yakonov-Perel mechanism, for semiconductors without inversion symmetry.
Bir-Aronov-Pikus mechanism, for heavily p-doped semiconductors.
Hyperfine interaction, for electrons bound on impurity sites or confined in a quantum dot.

The Bir-Aronov-Pikus mechanism and Hyperfine interaction are not relevant to the present application and so won't be elaborated.

The Elliot-Yafet mechanism is important for ‘small’ gap semiconductors with large spin-orbit splitting. In electron band structures the up-spin and the down-spin states are mixed by the spin-orbit interaction, which means the up(down) spin state respectively contains the down(up) spin state.

The ‘D'yakonov-Perel’ spin scattering is a form of spin orbit coupling and states that an electrical current in a semiconductor is accompanied by a ‘spin flow’ perpendicular to the current and directed from the bulk of the material to the surface. This leads to accumulation of spin aligned electrons into spin-polarized clusters in a thin layer in the semiconductor. See (Perel, 12 Jul. 1971). Thus, for optimum spin flow to occur on the semiconductor surface, the current through the material should be orientated parallel with the semiconductor surface.

Increasing the D'yakonov-Perel spin scattering effect will maximise the spin-aligned current and so a cathode construction and electrode alignment should be chosen to maximise this effect. Hence, preferred embodiments have electrode semiconductor surfaces 22, 24 aligned parallel with the interelectrode gap 19 and therefore, parallel with the direction of current flow through the electrodes 17, 18.

The spin-polarised clusters form in the semiconductor surface 22 due to the SHE mentioned above. The degree to which the spin-polarised clusters form depends not only on the semiconductor shape, thickness and material properties but also on the electrical current due to the so-called ‘skin effect’.

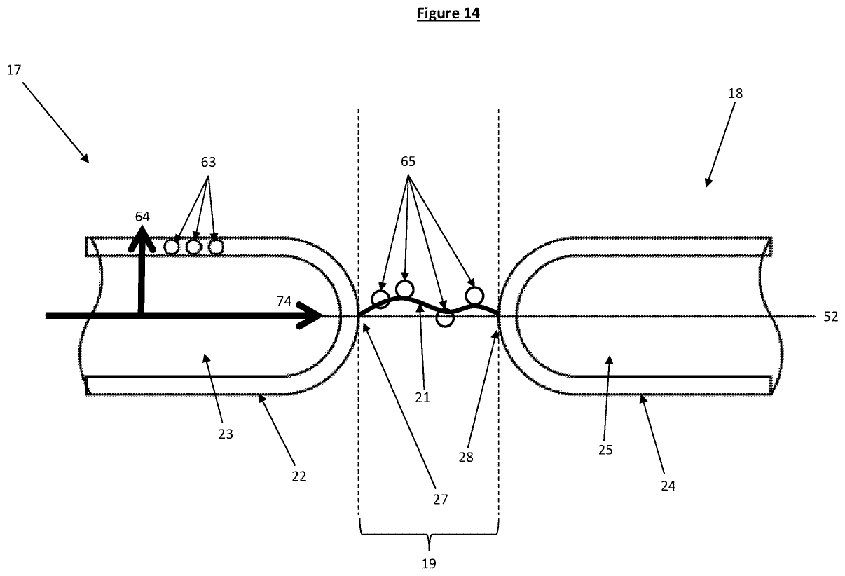

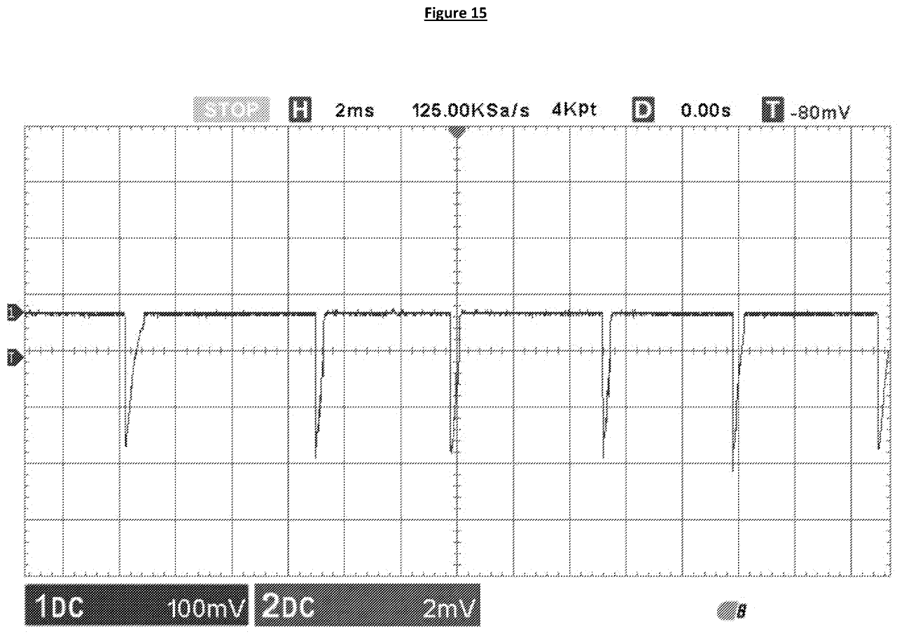

As is known in the art, the ‘skin effect’ is the tendency of an alternating electric current to become distributed within the current-carrying material such that the current density is largest near the surface and decreases exponentially with greater depth. Thus, the electric current flows mainly at the ‘skin’ of the current-carrying material, as indicated by arrow 64 in FIG. 14. In the preferred embodiments this ‘skin’ is the semiconductor surface 22. Thus, with a suitable semiconductor surface 22, the spin aligned electric current travels through the semiconductor surface 22.

The spin aligned current occurs across the entire semiconductor surface 22 and results in the spin-aligned current being distributed in two space dimensions on the semiconductor surface 22. The electric current thus manifests as a two-dimensional distribution of spin-aligned electron current flow on the semiconductor surface, akin to a quantum spin hall effect in the semiconductor surface.

The power supply 12 and electric pulse generation unit 40 produces a ‘skin effect’ through the current-carrying cathode 17 by applying very short duration electric potential ‘pulses’. The result is that the spin-aligned electrons are forced to the semiconductor surface 22 of the cathode 17 as indicated by arrow 64 in FIG. 14. The cathode 17 with semiconductor surface 22 can therefore act as a ‘spintronic’ device, capable of distributing the electrons in the surface according to their spin orientation.

This skin-effect and D'yakonov-Perel spin scattering is represented pictorially in FIGS. 13 and 14. FIG. 13 shows simplified electrodes 17, 18 and a current indicated by arrow 74 aligned parallel to the electric potential gradient. This causes the electrons to collect into clusters 63 having a common spin-state, i.e. adjacent spin-polarised currents of spin-up clusters 63 and spin-down clusters 63′.

The clusters 63, 63′ are pushed to the semiconductor surface 22, due to the skin effect. This force is indicated in FIG. 14 by arrow 64 aligned perpendicular to the direction of current 74 in the cathode 17.

FIG. 14 shows a simplified schematic representation of a longitudinal cross section though terminal peripheries 27, 28 of the electrodes 17, 18. The terminal peripheries 27, 28 are cuspate and located proximal the interelectrode gap 19. Both electrodes 17, 18 have a semiconductor surface 22, 24 covering respective conductive substrates 23, 25. The semiconductor surfaces 22, 24 proximal the interelectrode gap 19 are aligned parallel with an axis 52 of a direct traverse of the interelectrode gap 19. The current direction is indicated by arrow 74. An interelectrode discharge is indicated by line 21 and condensed plasmoid collections are represented by circles 65. The spin-polarised electron clusters 63 are indicated by circles 63 in the cathode semiconductor surface 22.

The distance between adjacent but oppositely spin-polarised electron clusters 63 in the semiconductor surface 22 is in the order of micrometres. This separation is close enough such that when emitted from the surface 22, oppositely spin-polarised electron clusters 63 will magnetically attract each other and chain together, forming ‘collections’ 65 of condensed plasmoids 62. The clusters 63, when emitted from the cathode 17, are termed ‘condensed plasmoids’.

The collections 65 are initially ‘pairs’ of oppositely spin-polarised clusters 62 that are magnetically attracted to each other. When emitted, the condensed plasmoid pairs tend to join with other pairs to form more complex chains such as those shown in FIGS. 6 and 7.

The reactor 4, 4b embodiments shown in FIGS. 9, 10, 11a and 11b attempt to maximise the skin effect as the semiconductor surface 22 is oriented parallel to the direction of the current 74 in the cathode 17 for almost the entirety of the surface 22.

In contrast, a parallel plate electrode arrangement (such as some prior art apparatus) with interelectrode discharges occurring between opposing planes of the plates produces only a minimal effect, as the electric current in the cathode is not aligned parallel with the cathode planar surface, instead oriented perpendicularly. Moreover, prior art parallel plate electrode arrangements naturally use conductive metal electrodes to minimise heat loss and minimise the voltage needed to initiate the discharge. The prior art was focused on producing condensed plasmoids with minimal voltage and heat and was not aware that a semiconductor surface could be used to more efficiently generate condensed plasmoids.

In the embodiment shown in FIG. 11c, the interelectrode discharges occur between the overlapping portions 53 of the electrodes 17, 18. The electric field and interelectrode current at the overlapping portions are thus not parallel with the current 74 in the cathode 17. Thus, while this arrangement will still produce some spin-polarised charge clusters 63 in the cathode 17, it will be less efficient due to a weakened skin effect at the overlapping portion. The overlapping portion of the semiconductor surface will not produce as many spin-polarised charge clusters 63 as the rest of the semiconductor surface 22.

The embodiment in FIG. 11d provides an improvement over that of the embodiment of FIG. 11c but is still not as efficient in producing condensed plasmoids 62 as the embodiment shown in FIG. 11a.

Another important factor in condensed plasmoid generation is the electron emission and plasma formation across the interelectrode gap 19. The electron emission from the semiconductor surface will now be explored.

Fowler-Nordheim tunnelling refers to the wave-mechanical tunnelling of electrons through a rounded triangular barrier created at the surface of an electron conductor by applying a very high electric field. Individual electrons can escape by Fowler-Nordheim tunnelling from many materials, in various circumstances.

One such example is known as Cold Field electron Emission (CFE). CFE is the name given to a particular statistical emission regime, in which the electrons in the emitter are initially in internal thermodynamic equilibrium, and in which most emitted electrons escape by Fowler-Nordheim tunnelling from electron states close to the emitter Fermi level. In contrast, in the ‘Schottky emission regime’ most electrons escape over the top of a field-reduced barrier, from states well above the Fermi level.

CFE can be achieved via a process known as the Malter effect. Following exposure to ionizing radiation, secondary electron emission from the surface of a thin insulating layer results in the establishment of a positive charge on the surface. This positive charge produces a high electric field in the insulator, resulting in the emission of electrons through the surface. This tends to pull more electrons from further beneath the surface. Eventually the process replenishes the lost electrons from collected electrons through the ground loop. This electron movement due to the Malter effect is often referred as an electron ‘avalanche’.

The Malter and CFE effects are thus important effects in spintronic applications such as the present invention.

Existing spintronic applications such as information processing may use spin-polarisation as the binary ‘0’s and ‘1’s for storing data. In such information processing applications, the spin current manipulation is importantly performed without a discharge current as discharge current is dissipative and generates heat. The resultant thermal ‘noise’ would therefore destroy the information carried by the spin. Thus, in information processing spintronic applications it is important that there is no, or minimal, discharge current.

In contrast, in the formation of condensed plasmoids 62, a discharge current in the plasma is required for the spin-polarised clusters 63 to emit and form condensed plasmoids 62 to traverse the interelectrode gap 19. It's therefore preferable that both:
a) CFE occurs so that the spin-polarised clusters 63 of electrons emit from near the cathode surface 22 without destruction, and thereby form condensed plasmoids 62, and
b) there is a discharge current 21 through a plasma between the electrodes 17, 18.

The semiconductor surface 22 is doubly advantageous for this application as it may act both to improve and align the spin polarisation and act as a ‘threshold switch’, effectively acting as an insulator up to a threshold electric field value and then behaving as a conductor when the electric field exceeds the threshold value. Thus, the semiconductor surface 22 may ensure that CFE occurs in the ‘effectively insulating state’ while at a high electric field (above the threshold), the semiconductor surface 22 becomes a better electric conductor, resulting in relatively little dissipation and minimal thermal noise generation. This combination ensures the spin-polarised state of the condensed plasmoids 63 is maintained during the interelectrode discharge.

In contrast, if the electrodes were instead made of a good conductor such as a metal (as in the prior art), during the short sparking discharge between the electrodes, about 80-90% of the input electric energy is lost as heat, sound and electromagnetic noise. Thus, condensed plasmoid formation is minimal and there is degradation of the cathode surface, as found in the prior art such as described by (Jaitner, 2019).

The interelectrode discharge 21 occurs spanning the interelectrode gap 19 when the Paschen condition is met, i.e. the electric field strength is sufficient given the gas pressure and inter-electrode gap distance. The triggering of the electron or Townsend ionisation avalanche happens at the cuspate terminal edge 27 of the cylindrical cathode 17.

An electron avalanche (Townsend ionisation) is a process in which a number of free electrons in the gas are subjected to strong acceleration by an electric field and subsequently collide with other atoms of the gas, thereby ionizing them (impact ionization). This releases additional electrons which accelerate and collide with further atoms, releasing more electrons, thereby forming a chain reaction. In a gas, this causes the affected region to become an electrically conductive plasma. This is visible as a blueish spark spanning the interelectrode gap 19.

This blue spark is produced because the SHE effect is not strong enough to ensure 100% of the current 74 is converted to spin-polarised clusters 63. Thus most (˜80%) of the current in the cathode 17 reaches the terminal edge 27 in an unpolarised state. This current, when emitted, forms the bluish spark provided by the interelectrode discharge 61.

The curvature of the terminal edge 27 of the cathode 17 is also an important parameter affecting the avalanche, as the point of highest curvature defines the electric field intensity required for the avalanche to occur. Hence, the terminal edge 27 is provided as a cuspate edge.

The spin-polarised clusters 63 of electrons may therefore be emitted from a semiconductor surface 22 if a threshold-exceeding electric current flows through the semiconductor surface 22. These clusters 63 then form condensed plasmoids 62 that collect together into collections 65 and traverse the interelectrode gap 19.

It has been observed in the prior art, and by the present inventor, that condensed plasmoids emit and form ‘collections’ of clusters, often as rings, chains or similar structures. Various hypotheses were proposed to explain this phenomena but the inventor posits that the condensed plasmoids form such collections due to the spin-polarisation of individual condensed plasmoids.

Electron spin defines a current and a corresponding magnetic moment. It follows that a spin ‘up’ electron will therefore be magnetically attracted to a spin ‘down’ electron if opposite poles are aligned. Thus, the electron clusters of the condensed plasmoids may behave as small magnetic dipoles. Adjacent clusters are thereby attracted to each other if they are close enough together to overcome the electrostatic repulsion. The clusters collect together, typically into a chain. This collection 65 is often a relatively long-lived stable structure, having a lifetime exceeding the electric potential pulse.

The semiconductor material used for the semiconductor surface 22 has a large effect on the spin-polarisation, electron emission and interelectrode discharge 61, and therefore condensed plasmoid formation. A number of desirable characteristics for an ideal semiconductor surface material are defined as follows.

The more insulating the semiconductor surface 22 is, the lower the electron mobility and density, thus requiring a higher electric field to move the electrons and cause cold field emission. However, the more insulating the semiconductor surface 22 is, the better the spin-polarisation efficiency. Thus, a compromise is sought between high carrier mobility vs spin-polarisation efficiency. A semiconductor surface 22 is thus chosen that optimises those parameters.

In the semiconductor surface 22, the constituent up-down spin-polarised clusters preferably occur equally, i.e. with the same number of net up-spin and net down-spin polarised clusters. There may thus be no overall net ‘spin current’ for the whole cathode 17, whilst still having an internal spin-polarised distribution.

The optimum semiconductor surface 22 will thus preferably maximise the proportion of current in the cathode semiconductor surface 22 that becomes spin-polarised electron clusters 63.

The semiconductor surface 22 material preferably has inversion asymmetry, i.e. it does not have inversion symmetry. As mentioned previously, it is important for condensed plasmoid formation that the D'yakonov-Perel’ scattering mechanism is dominant and thus a material without inversion symmetry is important. A material has an ‘inversion symmetry’ if, for every lattice point at r on the material there are corresponding lattice points at (−r). A material without inversion symmetry thus has electrons with both spin-up and spin-down states and it is not possible to permanently ‘invert’ the spin states, in contrast to a material with inversion symmetry.

The semiconductor surface 22 preferably has high carrier mobility i.e. as many free electrons as possible. Thus, many electrons can be emitted to maximise the number of condensed plasmoids 62 formed.

The semiconductor surface 22 preferably has low electron scattering at a surface-plasma interface. This property is important as the condensed plasmoids 62 cannot be formed if the electron scattering effect is too high. The process of emission of electrons crossing the semiconductor surface/plasma interface is a very brief phenomena, occurring in less than a femtosecond. However, this emission is vital for the formation of condensed plasmoids 62. The semiconductor surface quality, preparation and degradation all influence the degree of electron scattering and thus care taken to minimise these effects.

The semiconductor surface 22 preferably has a high dielectric constant. The dielectric constant of the semiconductor surface 22 also affects the cluster formation, whereby a higher dielectric constant is more likely to form spin-polarised electron clusters 63. In contrast, in pure metal cathodes, such as in the prior art, most of the electric current will form dissipative plasma and few spin-polarised electron clusters 63 will form.

A semiconductor surface 22 including a chalcogenide material meets many of these requirements. Chalcogenide materials that are glassy (amorphous), disordered, homogenous and/or isotropic are ideal.

Chalcogenide materials are a very poor conductor up to an opening threshold voltage, making it possible for spin-polarisation accumulation to occur. Above the opening threshold the resistance is suddenly reduced, allowing the spin-polarised clusters 63 to leave the cathode 17 with the interelectrode discharge 21 and thereby form condensed plasmoids 62.

The resistivity of a chalcogenide semiconductor material is in the range of 10⁻⁵ to 10⁸ Ωm, while for metallic materials the resistivity is in the range of 10⁻⁷ to 10⁻⁸ ωm. Metals are good conductors, with low spin ordering and spin coherence properties. Metals thus typically have a spin polarisation generation efficiency of well below 20%. In contrast, the efficiency of a chalcogenide semiconductor surface material is expected to be near full ordering, i.e. close to 100%. See (Hirohata, 2020).

The chalcogenide can be selected from group VI elements such as oxides, sulfides, selenides and/or tellurides. For example, an aluminium oxide or copper sulphide may be a suitable glassy chalcogenide for use as the semiconductor surface.

Some examples of Chalcogenide semiconductors used for different applications (electrical threshold switches) are described in (U.S. Pat. No. 3,271,591) by Ovshinsky.

Other studies that have researched Chalcogenide semiconductors include:
M. Popescu: Chalcogenides: Past, present and Future. Journal, of Non Crystalline Solids. Vol. 352, 2006, pp 887-89; and
S. Hudgens: Progress in Understanding the Ovshinsky effect. Phys. Status Solidi, Vol 249, No 10, 2012, pp 1951-1955.

In addition to the spin-polarisation and emission properties of the semiconductor surface 22 there are some properties of the semiconductor surface 22 that affect the physical and thermal operation of the cathode 17. The ideal cathode semiconductor surface 22 will thus have properties such as:
a low thermal expansion gradient, to prevent the deformation of the semiconductor surface under rapid electric potential loading and unloading of the cathode.
a high heat-conduction constant, to avoid melting as heat builds up in the semiconductor surface.
a high tensile strength, to avoid local cracking in case of heat expansion between the semiconductor surface and cathode substrate.
a high heat capacity, to store heat, thereby avoiding melting and surface erosion.
a high melting/softening temperature, to avoid melting and surface erosion.

In effect, the electrodes 17, 18 may be considered to behave in an analogous way to a ‘spin valve’ or a Johnson spin transistor. While not directly equivalent, a transistor is a useful analogy for visualising the operation. The semiconductor surface 22 can be considered analogous to a transistor emitter, the anode semiconductor surface 24 can be considered analogous to the transistor collector. The semiconductor surface work function defining the threshold switch property is analogous to a transistor gate, being open when the threshold electric field strength is exceeded.

Another important semiconductor surface parameter is the work function of the semiconductor surface 22. The work function, Φ of the semiconductor surface 22 is the energy needed to remove an electron from the surface into the vacuum. The work function is given as

$$W = - e ϕ - {E}_{F} ,$$

with −e being the charge of an electron, ϕ being the electrostatic potential in the vacuum near the surface and E_{F} being the Fermi energy, i.e. the electrochemical potential of electrons in the solid. The work function of the semiconductor surface varies not only with the element composition but also the surface structure. Thus, the semiconductor work function defines the threshold potential required for the electrons to emit from the semiconductor surface 22. A semiconductor surface 22 is therefore chosen with a work function that optimises the balance between emission of electrons and spin-polarisation.

The cathode 17 remains in an “open” state provided the electron discharge avalanche is maintained. However, as the goal is to generate condensed plasmoids, the electron discharge avalanche can only be maintained for a short duration due to the potential for the spin-polarisation dissipating.

The anode 18 receives any electrons that are not constrained within the condensed plasmoid collections 65 to reach the anode substrate and thereby the plasma ‘closes’ the electric circuit, enabling current flow.

The type of plasma discharge is also important for efficient condensed plasmoid formation.

As is known in the art, plasma discharge characteristics vary depending on the reactant gas, interelectrode gap distance, potential difference between electrodes, gas pressure and electrode material.

Plasma discharges are generally categorised into three or four known discharge types, including “dark”, “glow” and “spark/arc” discharges, with a “transitional” discharge defined between dark and glow discharges. This transitional region is where corona discharges occur. “Trichel pulses” are a known type of corona discharge.

Condensed plasmoids can form in both Trichel pulses or “spark” discharges. However, while Trichel pulses can produce stable condensed plasmoids, Trichel pulses have a low current. In contrast, glow discharges have a higher current but don't produce condensed plasmoids. Various prior art fusion experiments have been attempted in the glow discharge regime, such as Inertial-Electrostatic Confinement Fusion (IECF).

For preferred embodiments, where a high current may be desired, the reactor 4 is configured to produce spark discharges. The requirement to achieve a spark discharge restricts the flexibility of choosing different reactor parameters, as only certain combinations of parameters will produce a spark discharge. For a given interelectrode gap this means a higher voltage than other discharge types.

Existing experiments exploring plasma discharges have tended to explore the discharge characteristics with relatively large interelectrode gaps, i.e. greater than 5 mm, as this makes it easier to observe the discharges. However, preferred embodiments use an interelectrode gap distance of less than 5 mm, and 2 mm in the case of the embodiments of FIGS. 9-11. Thus plasma discharge characteristics in this region are relatively unexplored, requiring extensive experimentation to determine.

As will be described later, preferred embodiments apply a pulsed high voltage across the electrodes 17, 18. These short-period pulses produce transient spark discharges, which improve the generation efficiency of condensed plasmoids, in contrast to a constant spark discharge.

The condensed plasmoids 62 and condensed plasmoid collections 65 are beneficial in providing pseudo-particles with a very high electric field, which can be used to study several phenomena, including catalytic fusion.

Proton-Electron fusion is a known fusion reaction that can occur via the ‘weak force’. The specific quantum reaction may involve an up quark in the proton, exchanging a W boson with the electron. The W boson carries a unit of positive charge from the quark to the electron. In that process the up quark (charge+⅔) is converted to a down quark (charge of −⅓) so that the proton (spin=up up down) becomes a neutron (spin=up down down). The negatively charged electron is converted into an electron neutrino. The reaction is thus p+e−->n+vₑ where p=proton, e=electron, n=neutron and vₑ=neutrino.

A proton-electron fusion occurring within a proton-rich atom is known as “electron capture”. In radioactive decay, proton-electron fusion is a mode of beta decay in which an electron (commonly from an inner (low-energy) orbital) is ‘captured’ by the atomic nucleus. The electron reacts with one of the nuclear protons, forming a neutron and producing a neutrino.

Condensed plasmoids 62 may catalyze such a proton-electron reaction, as will now be described, with reference to FIG. 6c. FIG. 6c is a conceptual diagram to aid in understanding the reactions that occur and to show that the reactions occur on or near the surface of the condensed plasmoids 62. FIG. 6c is not intended to be an accurate depiction of position, size, ratios or other variables and should not be construed as such.

A condensed plasmoid 62 is a very dense cluster of spin-polarized electrons that binds with other condensed plasmoids 62 to form chain-like ‘collections’ 65 of condensed plasmoids 62. The condensed plasmoid collection 65 thus produces a very high localized negative electric potential and has a high mass, equal to the total mass of the constituent electrons. This electric potential and high mass may accelerate the ionized reactant gas nuclei (i.e. protons 58 with positive charge) in the gas in the chamber.

If a proton velocity reaches a critical threshold (with an energy of about 0.78 MeV) and the proton 57a comes close enough to an electron 58 of a condensed plasmoid 62, a proton-electron fusion reaction will occur, i.e.

p+e+0.78 MeV→n+v

This is represented in FIG. 6c with proton 57a and electron 58.

The rest mass of an electron and a proton is less than that of a neutron and thus additional energy must be supplied to form the neutron. This energy is provided by the 0.78 MeV acceleration of the proton and represents the mass deficiency to be supplied for energy to be conserved.

Electron-proton fusion may thus occur, resulting in a neutron 59 and neutrino (not shown). This generation of neutrons provides a catalyst for further fusion reactions.

The neutrons 59 produced are not detected outside of the chamber 15 and are considered ‘thermal’, low-energy or ‘cold’ neutrons, in contrast to ‘hot’ neutrons as formed from conventional fission reactions. Such low-energy neutrons 59 have a relatively larger reaction cross section and so more easily react with other particles.

A neutron 59 is electrically neutral and thus there is no Coulomb barrier to overcome in fusion reactions with protons. Neutron-proton and neutron-deuteron fusion reactions may thus occur at relatively low temperatures compared with ‘hot’ fusion deuterium-deuterium or deuterium-tritium reactions such as in magnetic tokamak reactors.

A neutron-proton fusion reaction may thus occur between the neutrons 59 emitted by the aforementioned electron-proton fusion step with further protons 57b accelerated toward the condensed plasmoid collections 65. The neutron-proton reaction forms a deuteron 60 and excess energy of about 2.224 MeV, i.e. the reaction is

p+n→d+2.224 MeV

The energy released corresponds to the loss in mass as a deuteron 60 has less mass than the combined mass of the proton 57b and neutron 59. This is also the binding energy of deuterium, i.e. about 2.224 MeV.

In turn, a deuteron-neutron fusion reaction may occur between the emitted deuterons 60 and other neutrons 59a, to thereby form a triton 61. This reaction is

d+n→t+6.258 MeV

Due to the heavy mass and significant charge of the condensed plasmoid collections 65 further reactions of the tritium 61 produced and further incoming accelerated protons 57c may occur, i.e.

$${T}_{3}^{1} + {p}_{1}^{1} = > {He}_{4}^{2}$$

These fusion reactions may occur as long as condensed plasmoids 62 are present and there is a source of protons 57 in the reactant gas. It should be noted that in use, millions of condensed plasmoids traverse the interelectrode gap during each discharge.

The ‘fuel’ for the reactor is thereby provided by the protons in the reactant gas and the condensed plasmoids behave as catalysts. Over time, as more reactions and transmutations occur, the proton ‘fuel’ will dissipate and further reactions will no longer be possible. However, the energy density available from nuclear fusion reactions is very high and thus even a relatively small quantity of gas can provide sufficient energy for many applications.

The neutrons generated may be bound near the surface of the condensed plasmoids due to the magnetic attraction between the neutrons and electrons on a condensed plasmoid 62. The energy released from the fusion reactions is thus released on the ‘surface’ of the condensed plasmoids 62.

When a fusion reaction occurs between such a ‘bound’ neutron and incoming proton or deuteron, the released energy destroys the corresponding condensed plasmoid. Electrons with a sufficiently high energy state will escape the bounds of the ‘parent’ condensed plasmoid and travel into the anode 18. It has been found that condensed plasmoids 62 tend to ‘leak’ electrons to the anode 18, even without a fusion reaction occurring, and so will naturally dissipate over time.

However, when the fusion reactions take place, some of the energy released is passed to the electrons of the condensed plasmoid 62, greatly increasing the number of high energy electrons that are free to move to the anode 18.

The energy released by the fusion reactions is thus passed to electrons in the condensed plasmoid 62. The energised electrons are ‘ejected’ from the condensed plasmoid 62 when the condensed plasmoid 62 is destroyed due to the energy release disrupting the magnetic and electric fields holding the condensed plasmoid together. The now free electrons move to the nearest location of lower potential, being the anode 18.

This results in an electron ‘cloud’ being ejected from the condensed plasmoids 62 to the anode 18 in a rapid burst. This electron cloud ejection occurs very rapidly, in a pulse in the order of magnitude of femtoseconds. When the electron ‘cloud’ reaches the anode 18 it is measured by voltmeter 51 as an output pulse with a large magnitude spike in electric potential, relative to ground.

Thus, some of the energy released by the fusion reactions is transferred to the electrons and manifests in the form of an electric pulse, in contrast to the heat generation that has been the goal of fusion reactors to date. The present invention thus provides a potentially far more efficient fusion system than heat-output fusion reactors, which require heat->electricity conversion with attendant energy losses.

The condensed plasmoid catalysed fusion reactions mentioned above are somewhat analogous to muon catalysed fusion i.e. with the condensed plasmoid acting as the catalyst instead of the muon. The condensed plasmoid collection 65 forms a highly charged pseudo-particle, analogous to a high-mass muon, which is used to draw particles together sufficiently for fusion to occur.

However, condensed plasmoids 62 have advantages over muons in that they have a much longer lifetime than a muon, a very high negative charge and a higher total energy. Generating condensed plasmoids 62 using the apparatus as aforementioned is also less energy expensive than generating muons. Thus, condensed plasmoids 62 may operate as the catalyst for a much longer time with less input energy requirements for generation than a muon.

The electron cloud has the side-effect of ionizing the surrounding gas molecules. This rapid ionization starts an acoustic pressure wave inside the chamber 15. Such an acoustic wave can be detected using a piezoelectric microphone and manifests as a coupled acoustic/electric wave inside the reactor chamber 15. A corresponding electric field forms which can be detected outside the chamber 15.

However, a drawback of the coupling of the acoustic and electric charge wave is that energy loss occurs due to inelastic scattering of the plasma gas molecules. The design of the chamber may thus be modified to optimise for the acoustic wave by tuning the chamber 15 and electrodes 17, 18 to the acoustic wave resonant frequency. For example, in one embodiment, the chamber volume may be variable by mounting one of the electrodes to an insulated, movable piston with a piston face acting as a closure to one end of the chamber. The piston movable axially along the chamber to change the chamber volume.

In addition to the condensed plasmoids emitting from the cathode 17,

Experimental results will now be described with respect to FIGS. 16-22.

The apparatus used in these experiments included the embodiment shown in FIGS. 9-11a with an interelectrode gap 19 of 5 mm and electrodes 17, 18 having a diameter of 8 mm at the terminal peripheries 27, 28.

A measured plot of an exemplary output anode voltage pulse at voltmeter 51 is shown in FIG. 16. The plot has a scale of 50V per voltage division and 100 ns per time division. The output voltage spike effectively includes a series of constituent pulses that correspond to reactions in the reactor 4 and corresponding electron clouds/waves reaching the anode 18. As is evident, a much larger (50-200V) output pulse is detected for a given input pulse of about 25V, though the output occurs over a much short duration. The total energy of the output pulse is higher than the total energy of the input pulse provided by the input circuit as the fusion reactions in the reactor have added energy to the electrons travelling through the interelectrode gap 19.

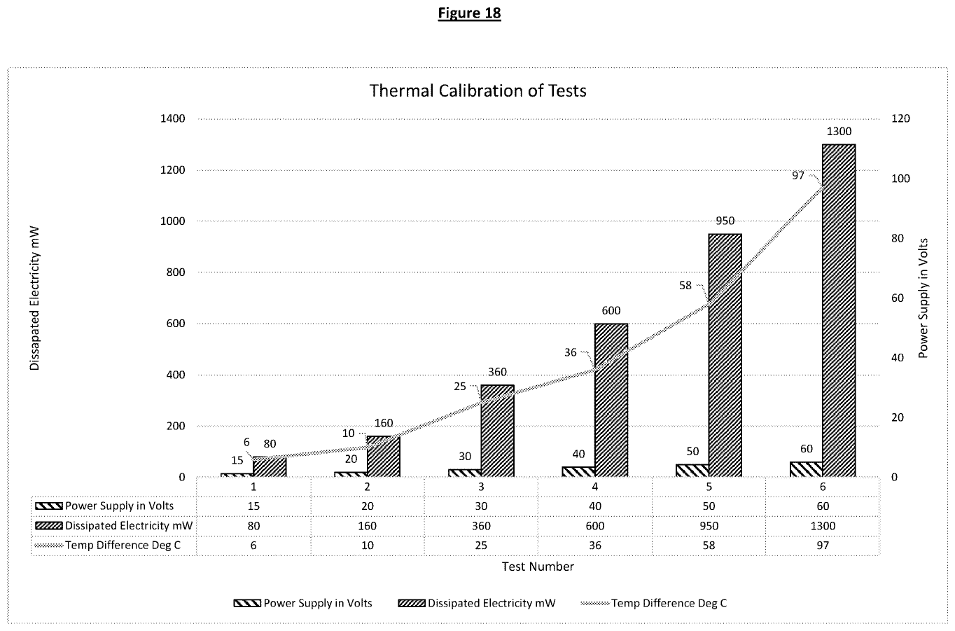

FIG. 18 shows a graph of thermal calibration tests corresponding to table A below. The thermal calibration tests were performed with a calibrated and known power source applying power to ohmic resistors in a calorimetry unit corresponding to the units 43a, 43b as shown in FIG. 12.

TABLE A
Thermal calibration used in tests

| power supply | dissipated electric | temperature |
|---|---|---|
| setting | power | difference |
| 15 V | 80 mW | 6° |
| 20 V | 160 mW | 10° |
| 30 V | 360 mW | 25° |
| 40 V | 600 mW | 36° |
| 50 V | 950 mW | 58° |
| 60 V | 1300 mW | 97° |

This calibration data was necessary to obtain to be able to accurately measure the dissipated energy in calorimetry units 43a, 43b.

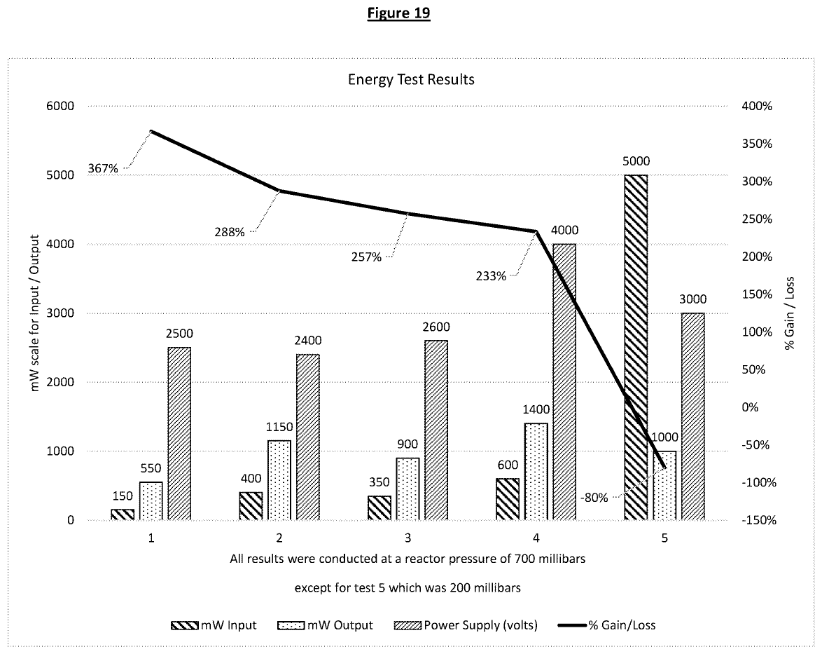

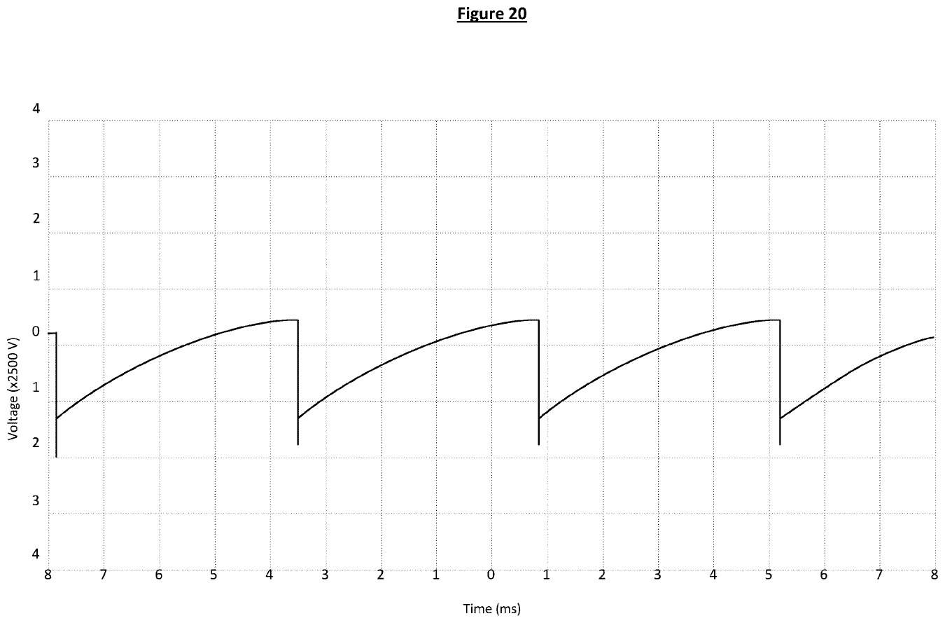

FIG. 19 shows a graph of test results corresponding to Table B below. These show the dissipated input power measured at flask 43a compared with the dissipated output power measured at flask 43b.

TABLE B
Test Results

| pressure | relax period | Cathode voltage | input | output power |
|---|---|---|---|---|
| (mbar) | millisecond | (V) | power mW | mW |
| 700 | 10 | 2500 V | 150 | 550 |
| 700 | 4.5 | 2600 V | 350 | 900 |
| 700 | 3.0 | 2400 V | 400 | 1150 |
| 700 | 2.5 | 4000 V | 600 | 1400 |
| 200 | 0.3 | 3000 V | 5000 | 1000 |

All the tests were taken at the same chamber pressure (700 mbar), except the last test which was performed at 200 mbar. The oscillator circuit 40 relaxation time period is determined by the voltage of the power supply 12 setting. The higher the power supply voltage, the faster the charging time of capacitor 41 and reduced relaxation time.

The input power is calculated as the input of the capacitor bank 41 divided by the time of the relaxation oscillation.

For each of the power measurements the power supply was tuned so that the relaxation period could be maintained uniformly for up to half an hour, such that the output electric power heating the calorimeter 43b reached a steady state condition. At higher power inputs and outputs, the relaxation periods were not uniform and therefore the energy balance tests were not reliable.

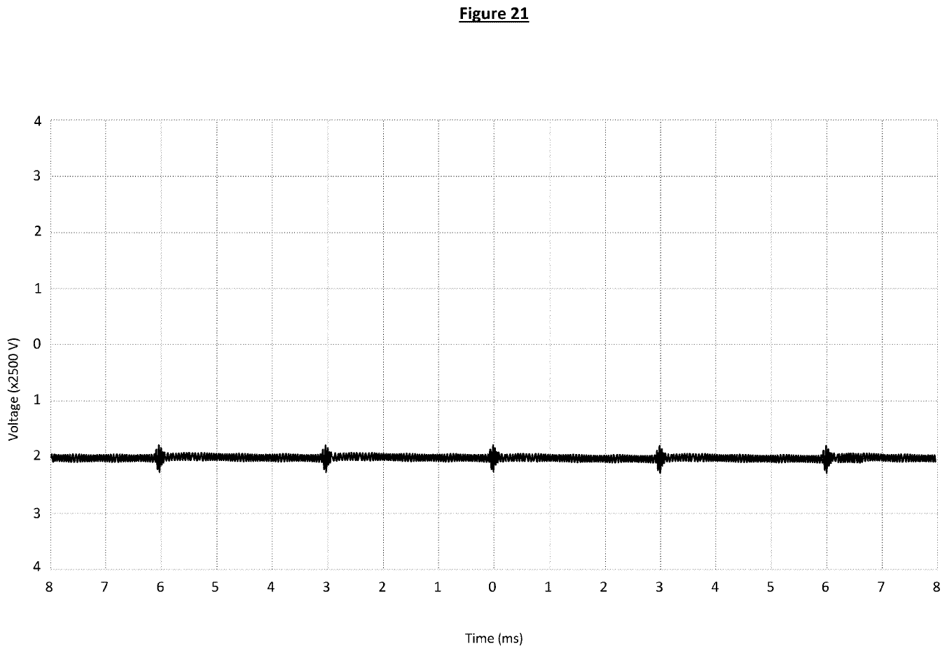

FIG. 20 shows an exemplary cathode voltage input trace. The input voltage shows a smooth sawtooth trace as the voltage increases and then discharges.

A control test was performed using dry air instead of a reactant gas (hydrogen). The air was dried by a silica gel pack. The air must be carefully dried, otherwise even a small amount of vapor may give sporadic results due to its hydrogen content.

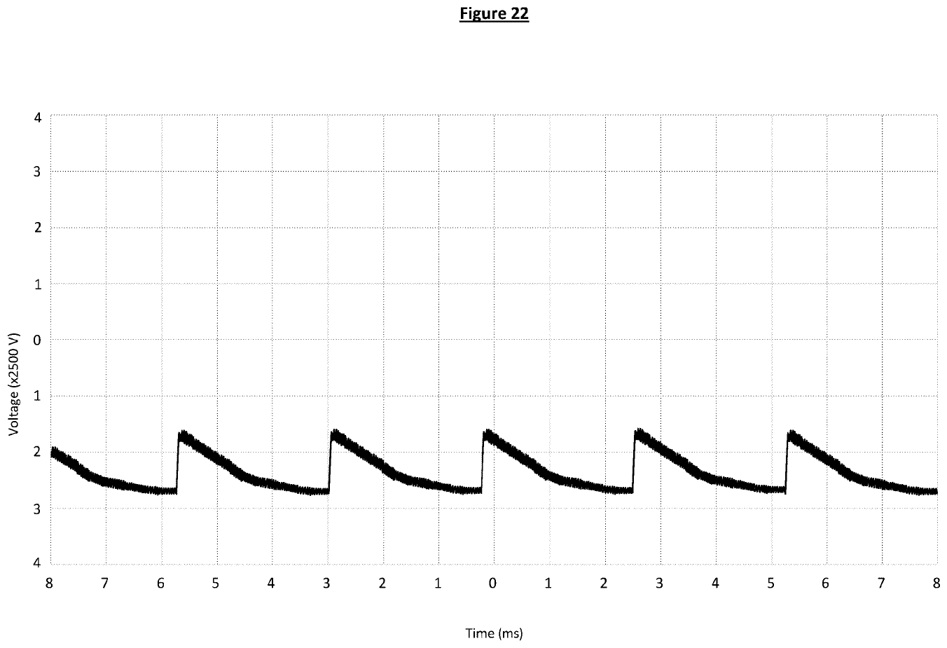

FIG. 21 shows a representative oscilloscope trace, representing the dry air test T_{A} as voltage against time with a 5 kV input pulses.

FIG. 22 in contrast shows a representative oscilloscope trace, representing the hydrogen test T_{H} as voltage against time with a 5 kV input pulses.

As is evident in comparing FIGS. 21 and 22, In the dry air tests, the voltage output in the output circuit 8 was the same or lower than the input voltage and decreased rapidly to zero, as expected for a dissipative system. In contrast, the hydrogen tests produced significantly higher energy output than the input from power supply 12.

It should be understood that there exist implementations of other variations and modifications of the invention and its various aspects, as may be readily apparent to those of ordinary skill in the art, and that the invention is not limited by the specific embodiments described herein. Features and embodiments described above may be combined with and without each other. It is therefore contemplated to cover any and all modifications, variations, combinations or equivalents that fall within the scope of the basic underlying principals disclosed and claimed herein.

### REFERENCES

B. M. Schasfoort and A. J. Tudas. (2008). The Handbook of Surface Plasmon Resonance. Royal Soc. of Chem. RSC Publishing.
Chen, S. a. (Vol. 10 No. 1, January 2020). A Possible Way to Realize Controlled Nuclear Fusion at Low Temperatures. World Journal of Nuclear Science and Technology.
Collie, J. N. (1914). The Production of Neon and Helium by Electrical Discharge. Proceedings of Royal Society London, Vol. 91-A, No. 623, 30-45.
Correa, P., & Correa, A. (1994). WO Patent No. 1994/009560.
Defour, J. (1993). Fusion Technology, Vol. 24, No. 2, 205-228.
Godes, R. (2018). US Patent No. 20190122774.
Gray, E. (1985). U.S. Pat. No. 4,661,747.
Hirohata. (2020). Review of Spintronics, Principles and Device Applications. Journal of Magnetism and Magnetic materials. Vol 509, 166.
Horvarth, S. (1979). U.S. Pat. No. 4,454,850.
Indech, R. (2003). US Patent No. 2005-0129160.
Jaitner, L. (2019). The Physics of Condensed Plasmoids (CPs). ICCF-22 Presentation.
Kenneth, S. (1992). U.S. Pat. No. 5,148,461.
Maier, S. A. (2007). Plasmonics: Fundamentals and applications. Springer.
Matsumoto, T. (1993). Cold Fusion Experiments with Ordinary Water and thin Nickel Foil. Fusion Technology, Vol. 24, No. 3, 296-306.
Mesyats, G. A. (2000). Cathode Phenomena in a vacuum discharge: The brakdown, the spark, and the arc.
Nasser, E. (1971). Fundamentals of Gaseous Ionization and Plasma Electronics. John Wiley, 266 FIG. 9.2a to FIG. 9.2g.
Ovshinsky. (n.d.). U.S. Pat. No. 3,271,591.
Papp, J. (1968). U.S. Pat. No. 3,670,494.
Perel, M. D. (12 Jul. 1971). Current induced spin orientation of electrons in semiconductors. Physics Letters, Vol 35A, number 6, 459-460.
Raether, H. (1988). Surface Plasmons on Smooth and Rough Surface and on Gratings. Springer.
Raizer, R. (1987). Gas Discharge Physics. Springer, 264, 265.
Rodney, C. E. (1988). Cauldrons of the Cosmos. University of Chicago Press.
Shoulders, K. (1990). U.S. Pat. No. 5,054,046.
Shoulders, K. (1991). U.S. Pat. No. 5,018,180.
Shoulders, K. (1991). U.S. Pat. No. 5,123,039.
Shoulders, K. (1991). U.S. Pat. No. 5,153,901.
Thomson, J. (1913). Appearance of Helium and Neon in Vacuum Tubes. Science, Vol. 37, No. 949, 360-364.
U. D. Kordjev and G. A. Mesyats. (1982). Nauka Publishers, page 213, FIGS. 8.8/1 to 8.8/4.

1. An apparatus for use in generating condensed plasmoids, the apparatus including a reactor, the reactor including:
a chamber for containing a reactant gas;
at least one pair of electrodes at least partially extending into the chamber, the at least one pair of electrodes including at least one cathode and at least one anode; and
an interelectrode gap formed between the at least one pair of electrodes;
wherein:
the at least one pair of electrodes include connections for connection to an electrical circuit, the electrical circuit including a power supply for applying an electric potential difference between the at least one pair of electrodes to form a plasma of the reactant gas in the interelectrode gap through which an interelectrode discharge traverses, and
the cathode has an electron discharge material, the electron discharge material including a semiconductor material from which clusters of electrons emit, thereby forming condensed plasmoids in the interelectrode discharge.

2. The apparatus as claimed in claim 1, wherein the semiconductor material includes a chalcogenide material.

3. The apparatus as claimed in claim 2, wherein the semiconductor material includes a chalcogenide material with at least one of the following properties:
glassy,
disordered,
chemically homogenous, and
porous.

4. (canceled)

5. The apparatus as claimed in claim 2, wherein the semiconductor material is a metal chalcogenide of a metal of nuclear spin greater than or equal to 5/2.

6. (canceled)

7. (canceled)

8. The apparatus as claimed in claim 1, wherein an exterior surface of at least part of the cathode is formed from the semiconductor material.

9. The apparatus as claimed in claim 1, wherein the exterior surface is inhomogeneous.

10. The apparatus as claimed in claim 1, wherein at least a portion of the exterior surface located proximal the interelectrode gap is aligned substantially coincident or parallel with an axis extending through a direct traverse of the interelectrode gap.

11. (canceled)

12. (canceled)

13. The apparatus as claimed in claim 1, wherein the semiconductor material forms a layer, coating, or surface treatment of a cathode substrate, and wherein the cathode substrate within the reactor chamber is completely covered by the semiconductor material such that the cathode substrate is not exposed directly to the reactant gas.

14. The apparatus as claimed in claim 1, wherein the reactant gas includes hydrogen- or hydrogen isotopes.

15. The apparatus as claimed in claim 1, wherein the reactant gas is a Penning-type mixture including a majority hydrogen, or hydrogen isotope, with an additive gas selected from the group including: helium, xenon, argon, acetylene, mercury.

16.-24. (canceled)

25. The apparatus as claimed in claim 1, wherein the electrodes each include a terminal periphery proximal the inter-electrode gap, the interelectrode gap being formed between the terminal peripheries, wherein the interelectrode gap has the same separation distance between all directly opposing portions of the terminal peripheries.

26.-28. (canceled)

29. The apparatus as claimed in claim 25, wherein the cathode terminal periphery is cuspate.

30.-32. (canceled)

33. The apparatus as claimed in claim 25, wherein the electrodes are cylindrical with circular terminal ends proximal the interelectrode gap, wherein the terminal peripheries are formed on the circular terminal ends and the terminal periphery lengths are approximately equal to the circumference of the terminal ends.

34. The apparatus as claimed in claim 33, wherein the electrodes have approximately the same diameter and are aligned coaxially.

35.-42. (canceled)

43. The apparatus as claimed in claim 1, wherein the anode also includes a semiconductor material.

44.-50. (canceled)

51. The apparatus as claimed in claim 1, wherein the electron discharge material has inversion asymmetry.

52.-54. (canceled)

55. The apparatus as claimed in claim 1, including an electrical circuit including a power supply, the electrodes connected to the electrical circuit, wherein the electrical circuit includes an electric pulse generation unit connected to the power supply, the electric pulse generation unit capable of applying a pulsed electrical potential difference between the cathode and the anode.

56.-59. (canceled)

60. The apparatus as claimed in claim 55, wherein the electrical circuit includes an input circuit and an output circuit, the input circuit including the power supply and electric pulse generation unit, and the output circuit including the output electrical circuitry, wherein the output circuit has the same impedance as that of the input circuit.

61.-64. (canceled)

65. A method of generating a condensed plasmoid using the apparatus as claimed in claim 1, the method including:
evacuating the chamber,
suppling a reactant gas to the chamber, and
applying an electric potential difference between the electrodes.

66. (canceled)

67. (canceled)

68. A reactor for an apparatus for use in generating condensed plasmoids, the reactor including:
a chamber for containing the reactant gas;
at least one pair of electrodes at least partially extending into the chamber, the at least one pair of electrodes including the at least one cathode and the at least one anode; and
an interelectrode gap formed between the at least one pair of electrodes;
wherein:
the at least one pair of electrodes include connections for connection to an electrical circuit, the electrical circuit including a power supply for applying an electric potential difference between the at least one pair of electrodes to form a plasma of the reactant gas in the interelectrode gap through which an interelectrode discharge traverses, and
at least the cathode has an electron discharge material including a semiconductor material.
